(19) United States
(12) Patent Application Publication
(10) Pub. No.: US 2025/0301858 A1
(43) Pub. Date: Sep. 25, 2025

(54) DISPLAY DEVICE

(71) Applicant: Samsung Display Co., Ltd., Yongin-si (KR)

(72) Inventors: Seungjun Lee, Yongin-si (KR); Jonghwa Park, Yongin-si (KR); Junggun Nam, Yongin-si (KR)

(21) Appl. No.: 18/899,865

(22) Filed: Sep. 27, 2024

(30) Foreign Application Priority Data
Mar. 21, 2024 (KR) 10-2024-0039256

(51) Int. Cl. H10K 59/122; H10K 77/10; H10K 102/00

(52) U.S. Cl. CPC H10K 59/122; H10K 77/111; H10K 2102/311

(57) ABSTRACT

A display device includes: a substrate; light-emitting diodes on the substrate; and a cover layer including: a cover frame on the substrate; and cover openings to overlap with the light-emitting diodes. The light-emitting diodes include: first light-emitting diodes located along a first line, the first line being a virtual closed curve having a first center point as a center; and second light-emitting diodes located along a second line, the second line being a virtual closed curve having the first center point as the center and surrounding around the first line. The cover openings include: first cover openings located along a third line, the third line being a virtual closed curve having the first center point as the center; and second cover openings located along a fourth line, the fourth line being a virtual closed curve having the first center point as the center and surrounding around the third line.

### CROSS-REFERENCE TO RELATED APPLICATION

The present application claims priority to and the benefit of Korean Patent Application No. 10-2024-0039256, filed on Mar. 21, 2024, in the Korean Intellectual Property Office, the entire disclosure of which is incorporated by reference herein.

### BACKGROUND

### 1. Field

Aspects of one or more embodiments of the present disclosure relate to a display device.

### 2. Description of the Related Art

Display devices may visually display electrical signals. Various display devices have been introduced that have excellent features, such as reduced thickness, light weight, and low power consumption. For example, flexible display devices that may be folded or rolled have been introduced. Recently, display devices having various structures, such as stretchable display devices that may be modified into various suitable shapes, are being researched.

The above information disclosed in this Background section is for enhancement of understanding of the background of the present disclosure, and therefore, it may contain information that does not constitute prior art.

### SUMMARY

One or more embodiments of the present disclosure may be directed to a display device, for example, such as a flexible display device.

Additional aspects and features will be set forth, in part, in the description that follows, and in part, may be apparent from the description, or may be learned by practicing one or more of the presented embodiments of the present disclosure.

According to one or more embodiments of the present disclosure, a display device includes: a display area and a non-display area; a substrate; a plurality of light-emitting diodes on the substrate; and a cover layer including: a cover frame on the substrate and including an opaque material; and a plurality of cover openings in the cover frame to overlap with the plurality of light-emitting diodes. The plurality of light-emitting diodes includes: a plurality of first light-emitting diodes located along a first line, the first line being a virtual closed curve having a first center point as a center; and a plurality of second light-emitting diodes located along a second line, the second line being a virtual closed curve having the first center point as the center and surrounding around the first line. The plurality of cover openings includes: a plurality of first cover openings located along a third line, the third line being a virtual closed curve having the first center point as the center; and a plurality of second cover openings located along a fourth line, the fourth line being a virtual closed curve having the first center point as the center and surrounding around the third line.

In some embodiments, a distance between the first center point and the first line may be greater than a distance between the first line and the second line.

In some embodiments, a distance between the first center point and the third line may be equal to a distance between the third line and the fourth line.

In some embodiments, the first line may surround around the third line; and the second line may surround around the fourth line.

In some embodiments, a modulus of the cover frame may be less than a modulus of the substrate.

In some embodiments, in a plan view, a size of each of the plurality of cover openings may be greater than a size of each of the plurality of light-emitting diodes.

In some embodiments, the plurality of light-emitting diodes may be symmetrically located with respect to a first center line and a second center line, the first center line being a virtual line passing through the first center point in a first direction, and the second center line being a virtual line passing through the first center point in a second direction crossing the first direction.

In some embodiments, the plurality of cover openings may be symmetrically located with respect to a first center line and a second center line, the first center line being a virtual line passing through the first center point in a first direction, and the second center line being a virtual line passing through the first center point in a second direction crossing the first direction.

In some embodiments, at least one of the first line, the second line, the third line, or the fourth line may be circular.

In some embodiments, the cover frame may include at least one of a thermoplastic polyurethane (TPU), a thermoplastic polyethylene (TPE), or a silicon rubber material.

In some embodiments, the cover layer may further include a support configured to support the cover frame from the substrate.

In some embodiments, the display device may further include a driver connected to a side of the substrate, and configured to drive the substrate to be radially stretched.

In some embodiments, the driver may include an expanding pulley structure.

According to one or more embodiments of the present disclosure, a display device that is convertible between a first structure and a second structure that is radially stretched from the first structure, includes: a substrate; a plurality of light-emitting diodes on the substrate; and a cover layer including: a cover frame on the substrate and including an opaque material; and a cover opening in the cover frame and overlapping with the plurality of light-emitting diodes. The plurality of light-emitting diodes includes: a plurality of first light-emitting diodes located along a first line, the first line being a virtual closed curve having a first center point as a center; and a plurality of second light-emitting diodes located along a second line, the second line being a virtual closed curve having the first center point as the center and surrounding around the first line. A difference between a distance between the first center point and the first line and a distance between the first line and the second line in the second structure is less than a difference between a distance between the first center point and the first line and a distance between the first line and the second line in the first structure.

In some embodiments, the cover opening may include: a plurality of first cover openings located along a third line, the third line being a virtual closed curve having the first center point as the center; and a plurality of second cover openings located along a fourth line, the fourth line being a virtual closed curve having the first center point as the center and surrounding around the third line. In each of the first structure and the second structure, a distance between the first center point and the third line may be equal to a distance between the third line and the fourth line.

In some embodiments, in the second structure, the first line may overlap with the third line.

In some embodiments, in the second structure, the second line may overlap with the fourth line.

In some embodiments, in the first structure, a distance between the first center point and the first line may be greater than a distance between the first line and the second line.

In some embodiments, in each of the first structure and the second structure, at least one of the first line, the second line, the third line, or the fourth line may be circular.

In some embodiments, the display device may further include a driver connected to a side of the substrate, and configured to drive the substrate to be radially stretched or reduced.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is a schematic perspective view of a display device according to an embodiment;

FIGS. 2A and 2B are perspective views showing a state in which the display device of FIG. 1 is stretched in a first direction;

FIG. 2C is a perspective view showing a state in which the display device of FIG. 1 is stretched in a second direction;

FIG. 2D is a perspective view showing a state in which the display device of FIG. 1 is stretched in the first direction and the second direction;

FIG. 2E is a perspective view showing a state in which the display device of FIG. 1 is stretched in a third direction;

FIG. 3 is a perspective view showing a state in which the display device of FIG. 1 is stretched radially;

FIG. 4 is a schematic plan view of a display device according to an embodiment;

FIG. 5A is a schematic plan view of a display device according to an embodiment;

FIG. 5B is a schematic cross-sectional view of a display device according to an embodiment;

FIG. 6A is a schematic plan view of a display device according to an embodiment;

FIG. 6B is a schematic cross-sectional view of a display device according to an embodiment;

FIG. 7 is a schematic plan view of a display device according to an embodiment;

FIG. 8 is a schematic exploded view of a driver according to an embodiment;

FIGS. 9 and 10 are schematic perspective views of a driver according to an embodiment;

FIG. 11 is a perspective view showing a state in which the display device of FIG. 1 is stretched radially;

FIGS. 12A and 12B are schematic plan views of a driver according to an embodiment;

FIGS. 13A and 13B are schematic plan views of a driver according to an embodiment;

FIGS. 14A-14C are equivalent circuit diagrams of a subpixel of a display device according to one or more embodiments; and

FIGS. 15A-15G are schematic perspective views showing various embodiments of electronic equipment including a display device according to one or more embodiments.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

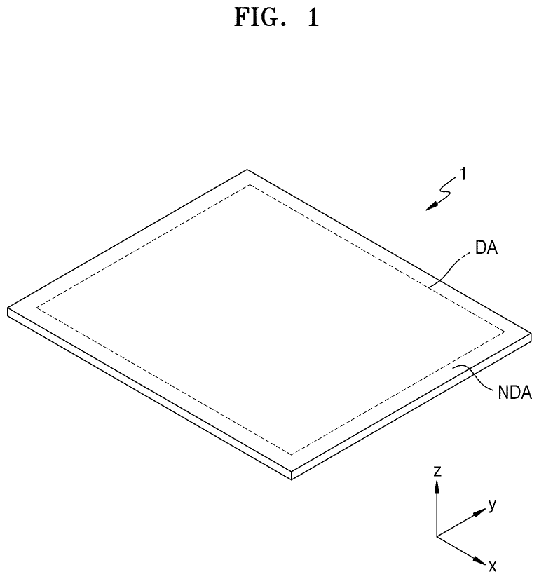

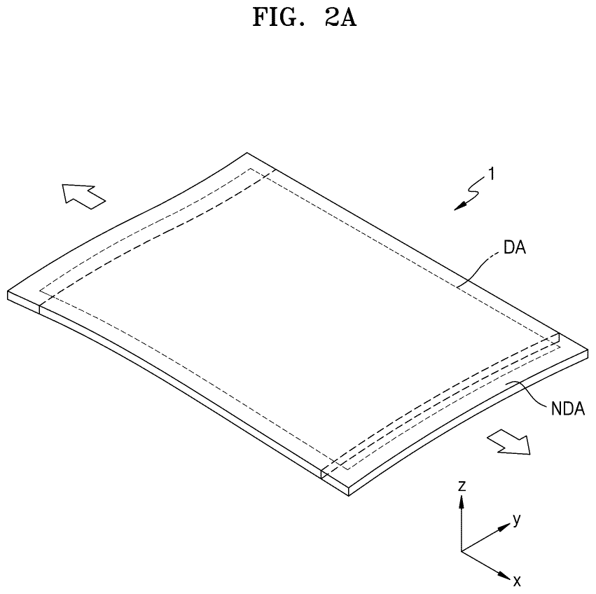

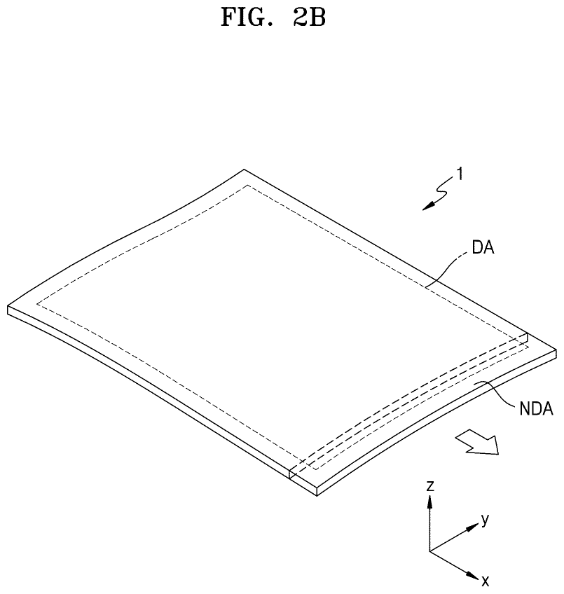

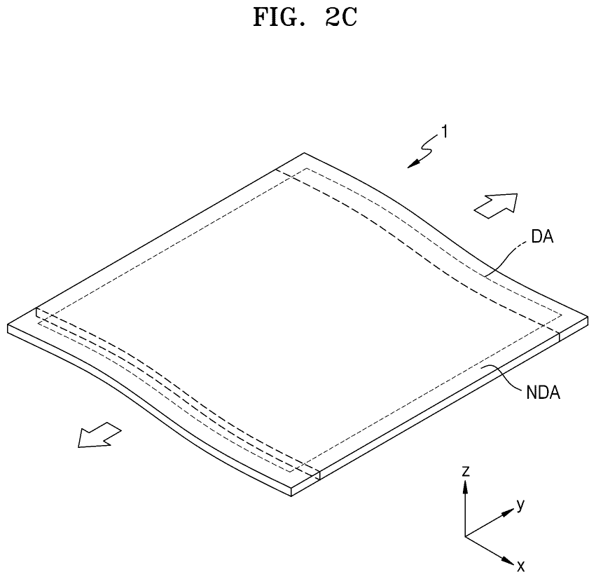

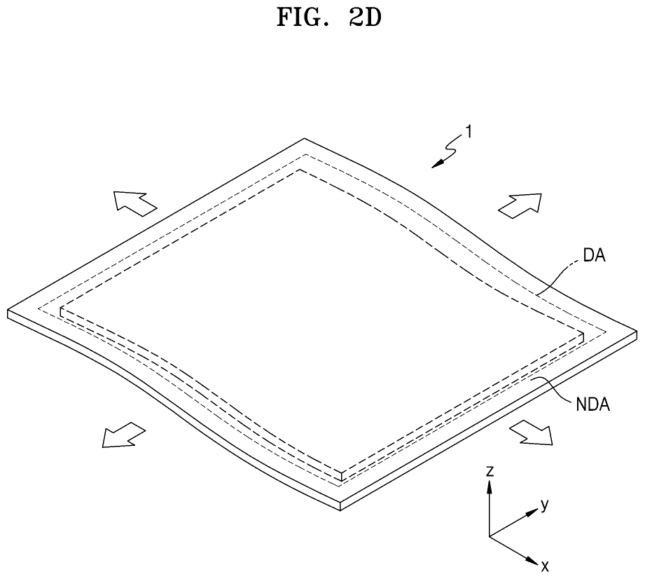

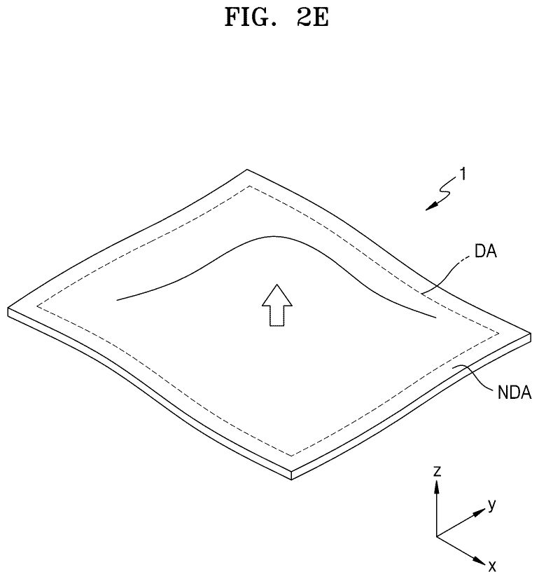

FIG. 1 is a schematic perspective view of a display device 1 according to an embodiment. FIGS. 2A and 2B are perspective views showing a state in which the display device 1 of FIG. 1 is stretched in a first direction. FIG. 2C is a perspective view showing a state in which the display device 1 of FIG. 1 is stretched in a second direction. FIG. 2D is a perspective view showing a state in which the display device 1 of FIG. 1 is stretched in the first direction and the second direction. FIG. 2E is a perspective view showing a state in which the display device 1 of FIG. 1 is stretched in a third direction.

Referring to FIG. 1, the display device 1 may include a display area DA and a non-display area NDA. The display area DA may include a plurality of pixels. The display device 1 may provide an image (e.g., a predetermined image) by using light emitted from the plurality of pixels. The non-display area NDA may be arranged outside the display area DA. The non-display area NDA is an area where the pixels are not arranged, and may entirely surround (e.g., around a periphery of) the display area DA.

The display device 1 may be stretched or reduced (e.g., relaxed or compressed) in various suitable directions. The display device 1 may be stretched in a first direction (e.g., the x direction and/or the −x direction) by an external force applied by an external object or a user. In some embodiments, as shown in FIGS. 2A and 2B, the display area DA and/or the non-display area NDA of the display device 1 may be stretched in the first direction (e.g., the x direction and/or the −x direction). For example, as shown in FIG. 2A, the display area DA and/or the non-display area NDA may be stretched in both the x direction and the −x direction, or as shown in FIG. 2B, the display area DA and/or the non-display area NDA may be stretched in the x direction while one side of the display device 1 is fixed.

The display device 1 may be stretched in a second direction (e.g., the y direction and/or the −y direction) by an external force applied by an external object or a user. In an embodiment, as shown in FIG. 2C, the display area DA and/or the non-display area NDA of the display device 1 may be stretched in the y direction and the −y direction. In some embodiments, the display device 1 may be stretched in the y direction or the −y direction while one side thereof is fixed.

The display device 1 may be stretched in a plurality of directions, such as the first direction (e.g., the x direction and/or the −x direction) and the second direction (the y direction and/or the −y direction), by an external force applied by a portion of an external object or the body of a user (e.g., a person). As shown in FIG. 2D, in some embodiments, the display area DA and/or the non-display area NDA of the display device 1 may be stretched in the ±x directions and ty directions.

The display device 1 may be stretched in a third direction (e.g., the z direction and/or the −z direction) by an external force applied by a portion of an external object or the body of a user. In an embodiment, as shown in FIG. 2E, a portion of the display device 1, such as a portion of the display area DA, may be stretched to protrude in the z direction. In some embodiments, a portion of the display device 1, such as a portion of the display area DA, may protrude in the −z direction (or may be submerged in the z direction).

FIGS. 2A to 2E show that the display device 1 is increased in the first direction, the second direction, and/or the third direction, but the present disclosure is not limited thereto. In some embodiments, the display device 1 may be varied in a variety of atypical shapes, such as being bent or twisted along two or more axes.

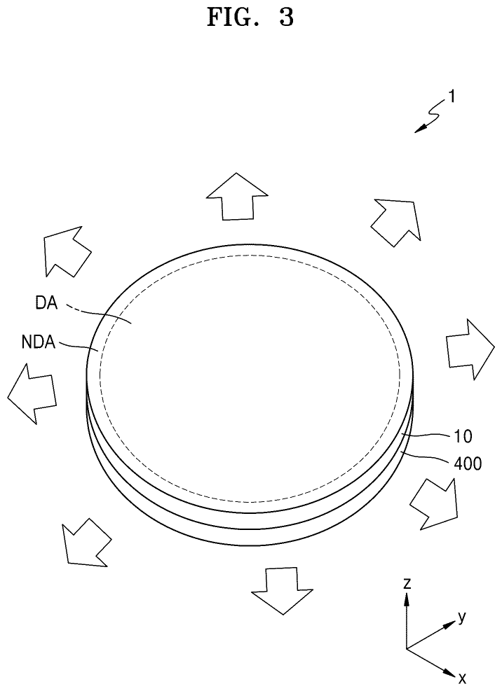

FIG. 3 is a perspective view showing a state in which the display device 1 of FIG. 1 is stretched radially.

The display device 1 may be stretched radially by an external object or an external force of the user. For example, the display device 1 may be circular, and may be stretched in a diameter direction from the center.

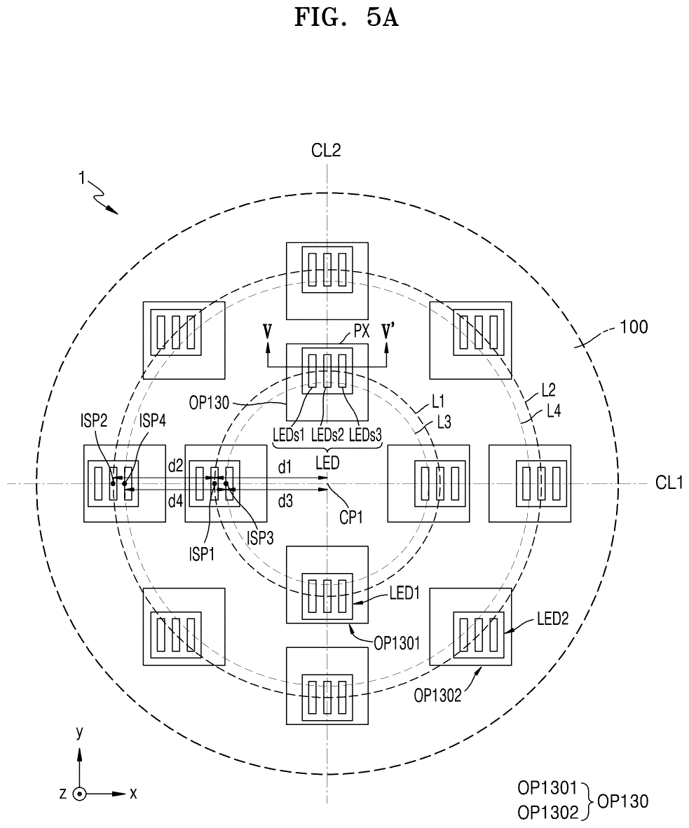

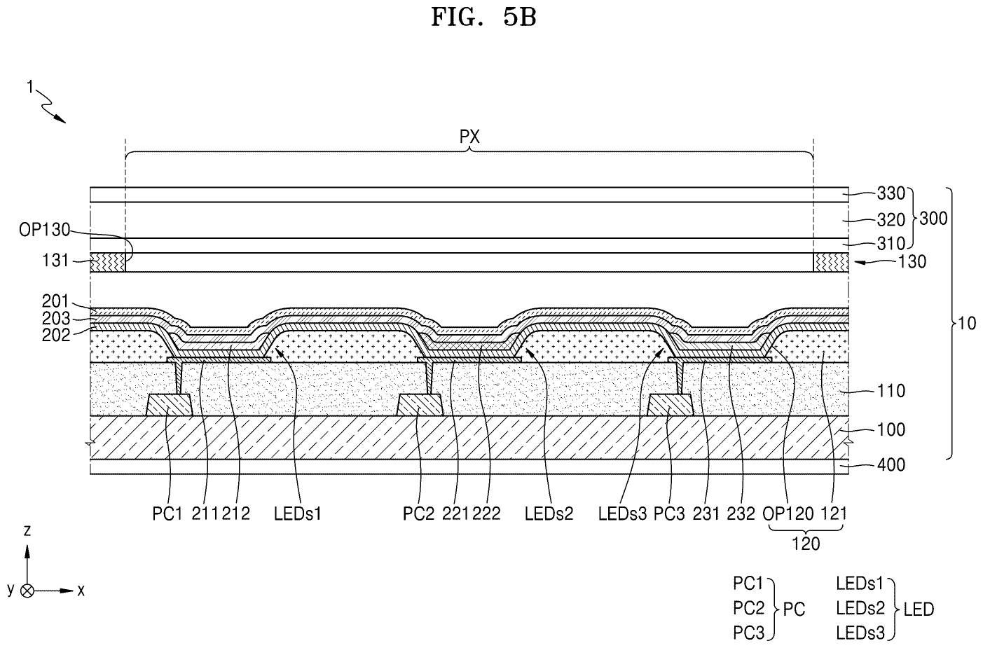

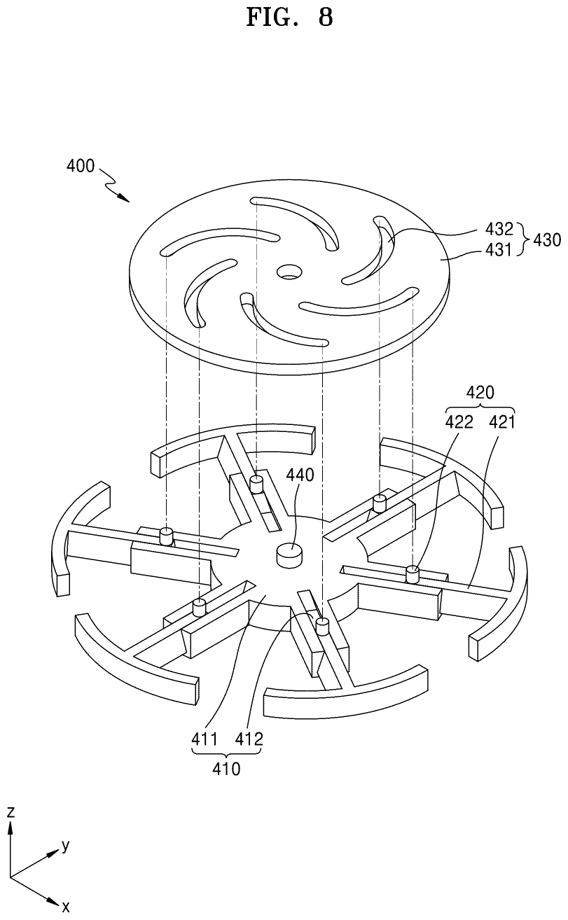

The display device 1 may include a display panel 10 and a driver 400. The display panel 10 may include the display area DA and the non-display area NDA described above with reference to FIG. 1. In an embodiment, the display area DA and/or the non-display area NDA may be radially stretched or reduced (e.g., radially relaxed or compressed). The driver 400 may be fixed to one side (e.g., the rear surface) of the display panel 10, and may provide a driving force to the display panel 10, such that the display panel 10 is stretched or reduced. The display panel 10 will be described in more detail below with reference to FIG. 5B. In addition, the driver 400 will be described in more detail below with reference to FIGS. 8 to 10.

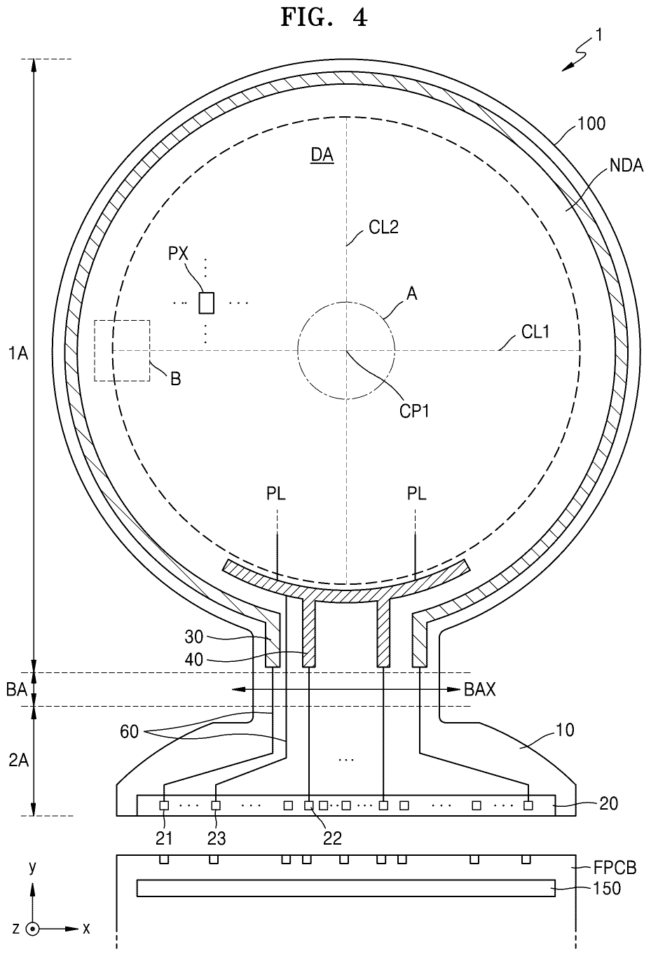

FIG. 4 is a schematic plan view of the display device 1 according to an embodiment.

As described above with reference to FIG. 3, the display device 1 may include the display panel 10 and the driver 400. The display panel 10 of the display device 1 is described in more detail hereinafter with reference to FIG. 4.

Referring to FIG. 4, the display panel 10 may include a substrate 100. The substrate 100 may include a first area 1A, a second area 2A, and a bending area BA. In this case, the first area 1A may be a display portion, and the second area 2A may be a connector portion connected to an external device. In this case, because the display area DA is exposed to the outside, the display portion may implement an image according to an operation of the display area DA. As described above, the display area DA may be included in the first area 1A, and the non-display area NDA may include a portion excluding the display area DA of the first area 1A, the second area 2A, and the bending area BA.

For convenience of illustration, hereinafter, a center point of the display area DA is referred to as a first center point CP1, a virtual line passing through the first center point CP1 in the first direction (e.g., the x direction and/or the −x direction) is referred to as a first center line CL1, and a virtual line passing through the first center point CP1 in the second direction (e.g., the y direction and/or the −y direction) crossing the first direction is referred to as a second center line CL2. An angle between the first center line CL1 and the second center line CL1 may be a right or substantially right angle.

The display area DA may have a symmetrical or substantially symmetrical shape with respect to the first center line CL1 and the second center line CL2. For example, the display area DA may be circular with the first center point CP1 as the center thereof. However, the present disclosure is not limited thereto, and the shape of the display area DA may be variously modified as needed or desired. For example, the display area DA may be elliptical with the first center point CP1 as the center thereof.

The substrate 100 may include the bending area BA extending in the first direction (e.g., the x direction or the −x direction). The bending area BA is arranged between the first area 1A and the second area 2A with respect to the second direction (e.g., the y and/or the −y direction) crossing the first direction. For example, the substrate 100 may be bent with respect to a bending axis BAX extending in the first direction (e.g., the x direction and/or the −x direction).

The first area 1A may include the display area DA. As shown in FIG. 4, in addition to the display area DA, the first area 1A may also include a portion of the non-display area NDA outside the display area DA. The second area 2A includes another portion of the non-display area NDA.

The display area DA includes a plurality of pixels PX to implement an image. The plurality of pixels PX may be implemented by a display element, and the display element may be driven by a pixel circuit connected thereto. The pixel circuit may include a suitable element, such as a thin film transistor (TFT) and a storage capacitor. The pixel circuit may be connected to a scan line, and a data line crossing the scan line. In addition, the pixel circuit may be connected to a driving voltage line PL.

The non-display area NDA of the first area 1A, in which the pixels PX are not arranged, does not provide an image. A first power supply line 30 and a second power supply line 40 for applying different power voltages from each other may be arranged in the non-display area NDA. In addition, a scan driver may be arranged in the non-display area NDA.

In the non-display area NDA, the first power supply line 30 may surround (e.g., around a periphery of) at least a portion of the display area DA. The first power supply line 30 may surround (e.g., around a periphery of) most of the display area DA, except for a portion in which the second power supply line 40 is arranged in the non-display area NDA. In some embodiments, the first power supply line 30 may surround (e.g., around a periphery of) a portion of the second power supply line 40. The first power supply line 30 may be electrically connected to an opposite electrode of the display elements arranged in the display area DA, and may transmit a common voltage. The first power supply line 30 may be connected to a pad 21 of a pad portion 20. Because the first power supply line 30 is connected to the pad 21, the first power supply line 30 may include a portion extending to the pad portion 20, for example, such as a portion extending in the −y direction.

In the non-display area NDA, the second power supply line 40 may be arranged correspondingly with a lower end portion of the display area DA. A plurality of driving voltage lines PL may be connected to the second power supply line 40 to transmit a driving voltage to the plurality of pixels PX arranged in the display area DA. The second power supply line 40 may be connected to a pad 22 of the pad portion 20. Because the second power supply line 40 is connected to the pad portion 20, the second power supply line 40 may include a portion extending to the pad portion 20, for example, such as a portion extending in the −y direction.

The scan driver may be arranged in the non-display area NDA adjacent to a portion of the display area DA. For example, the scan driver may be arranged on the left, the right, or both (e.g., opposite) sides of the display area DA. A scan signal generated by the scan driver may be provided to the pixels PX via the scan line. In some embodiments, the scan driver may be arranged in a portion of the display area DA adjacent to the non-display area NDA.

The pad portion 20 may be arranged in the second area 2A. The pad portion 20 includes a plurality of pads 21, 22, and 23. The pad portion 20 may not be covered by an insulating layer to be exposed, and thus, the pad portion 20 may be electrically connected to a controller, such as a flexible printed circuit board FPCB or a driver 150.

The driver 150 may be arranged in a separate flexible printed circuit board FPCB, and the flexible printed circuit board FPCB may be connected to the pad portion 20. In some embodiments, the driver 150 may be arranged in various suitable ways. For example, the driver 150 may be directly disposed on a portion of the substrate 100 extending and protruding from the substrate 100 by using a chip-on-glass (COG) method or a chip-on-plastic (COP) method.

The controller may change a plurality of image signals received from an external source into a plurality of image data signals, and may transmit the changed signals to the display area DA through the pad portion 20. In addition, the controller may receive a vertical synchronous signal, a horizontal synchronous signal, and a clock signal, may generate a control signal for controlling the driving of the scan driver, and may transmit the control signal to the scan driver through the pad portion 20. The controller may transmit different voltages to each of the first power supply line 30 and the second power supply line 40 through the pad portion 20. The pad portion 20 may be connected to a plurality of fanout wirings 60, and may transmit the voltage and various signals to the display area DA.

The plurality of fanout wirings 60 may overlap with the bending area BA. The fanout wirings 60 may extend from the first area 1A across the bending area BA to the second area 2A. The fanout wirings 60 may extend in a direction crossing the bending axis BAX. The fanout wirings 60 may be arranged in various suitable ways, such as being arranged to be perpendicular to or substantially perpendicular to the bending axis BAX or crossing the bending axis BAX at a suitable angle (e.g., a predetermined angle). In addition, the fanout wirings 60 may have various suitable shapes, such as a curved shape or a zigzag shape, that is different from (e.g., not) a straight line shape.

FIG. 5A is a schematic plan view of the display device 1 according to an embodiment. FIG. 5B is a schematic cross-sectional view of the display device 1 according to an embodiment.

In more detail, FIG. 5A is an enlarged view of the region A of FIG. 4, and FIG. 5B is a cross-sectional view taken along the line V-V′ of the display device 1 of FIG. 5A.

Referring to FIGS. 5A and 5B, the display device 1 may include the display panel 10 and the driver 400. The display panel 10 may include the substrate 100, a circuit element layer 110, a light-emitting diode LED, a bank layer 120, a cover layer 130, and an encapsulation layer 300.

The substrate 100 may include a polymer resin, such as polyethersulfone, polyarylate, polyether imide, polyethylene naphthalate, polyethylene terephthalate, polyphenylene sulfide, polyimide, polycarbonate, cellulose triacetate, and/or cellulose acetate propionate. In an embodiment, the substrate 100 may be a single layer including a polymer resin as described above. In some embodiments, the substrate 100 may have a multilayered structure including a base layer including a polymer resin as described above, and a barrier layer including an inorganic insulating material. The substrate 100 including the polymer resin may have a flexible, rollable, and/or bendable characteristic.

The circuit element layer 110 may be disposed on the substrate 100. The circuit element layer 110 may include a pixel driving circuit portion PC. The pixel driving circuit portion PC may include a thin film transistor and a storage capacitor. Layers included in the TFT and the storage capacitors, such as semiconductor layers and electrode layers, may be arranged with an insulating layer therebetween. A plurality of pixel driving circuit portions PC may be provided. The plurality of pixel driving circuit portions PC may be spaced apart from each other. For example, the pixel driving circuit portion PC may include a first pixel driving circuit portion PC1, a second pixel driving circuit portion PC2, and a third pixel driving circuit portion PC3 that are spaced apart from one another.

The bank layer 120 may be disposed on the circuit element layer 110. The bank layer 120 may include an organic material or an inorganic material. When the bank layer 120 includes an organic material, the bank layer 120 may include at least one organic insulating material selected from the group consisting of polyimide, polyamide, an acrylic resin layer, benzocyclobutene, and a phenol resin layer. When the bank layer 120 includes an inorganic material, the bank layer 120 may have a single layer or multiple layers including one or more of silicon oxide (SiOx), silicon nitride (SiNx), and/or silicon oxynitride (SiON).

The light-emitting diode LED may be disposed on the substrate 100. In more detail, the light-emitting diode LED may be disposed on the circuit element layer 110, and may be electrically connected to the pixel driving circuit portion PC. The light-emitting diode LED may include a plurality of sub light-emitting diodes LEDs1, LEDs2, and LEDs3 (hereinafter, also referred to as a first sub light-emitting diode LEDs1, a second sub light-emitting diode LEDs2, and a third sub light-emitting diode LEDs3). For example, the light-emitting diode LED may include a first sub light-emitting diode LEDs1, a second sub light-emitting diode LEDs2, and a third sub light-emitting diode LEDs3. The first sub light-emitting diode LEDs1, the second sub light-emitting diode LEDs2, and the third sub light-emitting diode LEDs3 may be arranged to be spaced apart from each other. The first sub light-emitting diode LEDs1 may be electrically connected to the first pixel driving circuit portion PC1. The second sub light-emitting diode LEDs2 may be electrically connected to the second pixel driving circuit portion PC2. The third sub light-emitting diode LEDs3 may be electrically connected to the third pixel driving circuit portion PC3.

The first sub light-emitting diode LEDs1 may include a first pixel electrode 211, a first emission layer 212, a common electrode 201, a first functional layer 202, and a second functional layer 203. The second sub light-emitting diode LEDs2 may include a second pixel electrode 221, a second emission layer 222, the common electrode 201, the first functional layer 202, and the second functional layer 203. The third sub light-emitting diode LEDs3 may include a third pixel electrode 231, a third emission layer 232, the common electrode 201, the first functional layer 202, and the second functional layer 203.

The first to third pixel electrodes 211, 221, and 231 may be disposed to be spaced apart from each other on the circuit element layer 110. The first to third pixel electrodes 211, 221, and 231 may include one or more conductive oxides, such as indium tin oxide (ITO), indium zinc oxide (IZO), zinc oxide (ZnO), indium oxide (In₂O₃), indium gallium oxide (IGO), or aluminum zinc oxide (AZO). In some embodiments, the first to third pixel electrodes 211, 221, and 231 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a suitable compound thereof. In some embodiments, the first to third pixel electrodes 211, 221, and 231 may further include a layer formed by disposing ITO, IZO, ZnO, or In₂O₃ on/under the reflective layer.

The bank layer 120 may be disposed on the first to third pixel electrodes 211, 221, and 231. The bank layer 120 may include a cover portion 121 and a bank opening OP120. The cover portion 121 may cover an end of each of the first to third pixel electrodes 211, 221, and 231. In addition, the bank opening OP120 may expose a portion of each of the first to third pixel electrodes 211, 221, and 231.

The first emission layer 212, the second emission layer 222, and the third emission layer 232 may be disposed on the first pixel electrode 211, the second pixel electrode 221, and the third pixel electrode 231, respectively. The first to third emission layers 212, 222, and 232 may be accommodated in the bank opening OP120 of the bank layer 120. The first to third emission layers 212, 222, and 232 may include a high molecular or low molecular organic material for emitting light of a desired color (e.g., a predetermined color). As another example, the first to third emission layers 212, 222, and 232 may include an inorganic light-emitting material or quantum dots. The first to third emission layers 212, 222, and 232 may emit light of different colors from each other. For example, the first emission layer 212 may emit red light, the second emission layer 222 may emit green light, and the third emission layer 232 may emit blue light.

The common electrode 201 may be disposed on the first to third emission layers 212, 222, and 232. The common electrode 201 may cover the bank layer 120. The common electrode 201 may include a conductive material having a low work function. For example, the common electrode 201 may include a transparent (or transflective) layer including Ag, Mg, Al, Pt, Pd, Au, Ni, Nd, Ir, Cr, lithium (Li), calcium (Ca), or a suitable alloy thereof. As another example, the common electrode 201 may further include a layer, such as ITO, IZO, ZnO, or In₂O₃, on the transparent (or transflective) layer including one or more of the materials described above.

The first functional layer 202 may be arranged between the first to third emission layers 212, 222, and 232, and between the first to third pixel electrodes 211, 221, and 231. The first functional layer 202 may be disposed on the bank layer 120. For example, the first functional layer 202 may include a hole transport layer (HTL), or may include an HTL and a hole injection layer (HIL).

The second functional layer 203 may be arranged between the first to third emission layers 212, 222, and 232 and the common electrode 201. For example, the second functional layer 203 may include an electron transport layer (ETL) and/or an electron injection layer (EIL).

The first functional layer 202, the second functional layer 203, and the common electrode 201 may be sequentially stacked on the cover portion 121 of the bank layer 120. The first functional layer 202, the second functional layer 203, and the common electrode 201 may be common layers covering the substrate 100 entirely or substantially entirely.

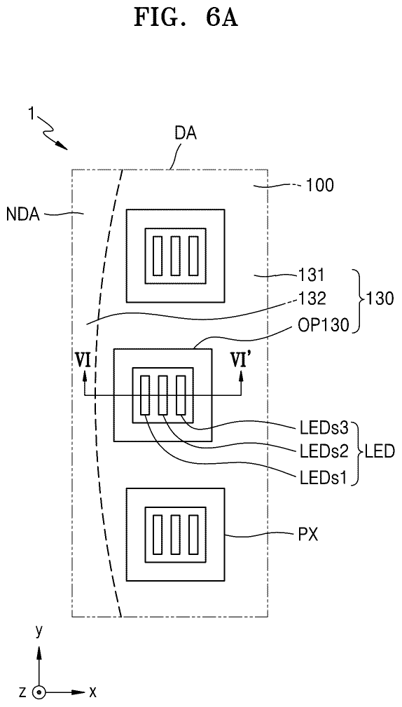

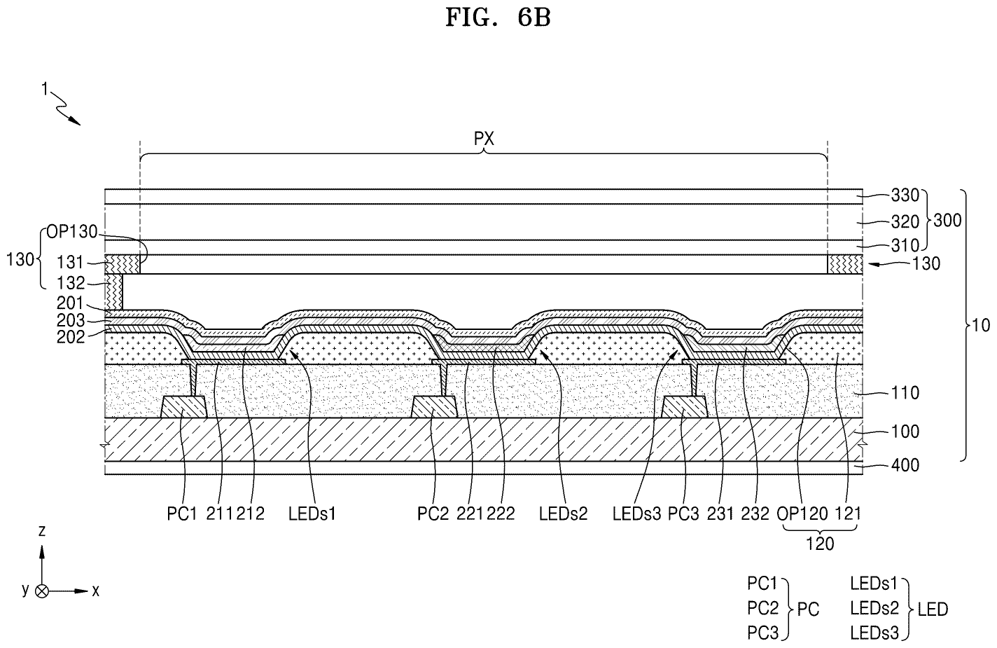

The cover layer 130 may be disposed on the substrate 100. The cover layer 130 may be disposed on the common electrode 201 of the light-emitting diode LED. The cover layer 130 may include a cover frame 131, a support 132 (e.g., refer to FIG. 6A), and a cover opening OP130.

The support 132 is described in more detail below with reference to FIGS. 6A and 6B.

The cover frame 131 may be disposed on the substrate 100, and may be spaced apart from the common electrode 201. The cover frame 131 may include an opaque material. For example, the cover frame 131 may include at least one of a thermoplastic polyurethane (TPU), a thermoplastic polyethylene (TPE), and/or a silicon rubber material.

The cover opening OP130 may be disposed at (e.g., in or on) the cover frame 131. The cover opening OP130 may pass through (e.g., may penetrate) the cover frame 131. The cover opening OP130 may overlap with the light-emitting diode LED. For example, one cover opening OP130 may overlap with the first sub light-emitting diode LEDs1, the second sub light-emitting diode LEDs2, and the third sub light-emitting diode LEDs3. The light-emitting diode LED may be exposed to the outside of the cover frame 131 by the cover opening OP130. Light emitted from the light-emitting diode LED may be displayed externally through the cover opening OP130. Thus, the light-emitting diode LED may be defined as the pixel PX.

The encapsulation layer 300 may be disposed on the substrate 100. The encapsulation layer 300 may be disposed on the cover layer 130. The encapsulation layer 300 may be supported by the cover layer 130. The encapsulation layer 300 may include at least one inorganic layer and at least one organic layer. For example, the encapsulation layer 300 may include a first inorganic encapsulation layer 310, an organic encapsulation layer 320, and a second inorganic encapsulation layer 330 that are sequentially stacked, but the present disclosure is not limited thereto, and the encapsulation layer 300 may include various suitable configurations.

The first inorganic encapsulation layer 310 and the second inorganic encapsulation layer 330 may include at least one material selected from the group consisting of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride.

The organic encapsulation layer 320 may include at least one material selected from the group consisting of an acrylic resin layer, a methacrylic resin layer, polyisoprene, a vinyl-based resin layer, an epoxy-based resin layer, a urethane-based resin layer, a cellulose-based resin layer, and a perylene-based resin layer.

FIG. 5B illustrates an example in which the encapsulation layer 300 is formed on the plurality of light-emitting diodes LED, but the present disclosure is not limited thereto. In other words, the display device 1 may include a sealing substrate instead of the encapsulation layer 300. The sealing substrate may be bonded with the substrate 100 by a sealing member, such as a sealing glass frit, to block external moisture and air.

In the present embodiment, various functional layers, such as a polarizing layer, a color filter layer, a touch screen layer, and/or the like, may be further disposed on the encapsulation layer 300.

A first structure of the display device 1 has been described above with reference to FIGS. 4 and 5A. The first structure of the display device 1 may be a structure before the display device 1 is stretched.

A virtual closed curve having a first center point CP1 as the center is referred to as a first line L1. A virtual closed curve having the first center point CP1 as the center and surrounding (e.g., around a periphery of) the first line L1 is referred to as a second line L2.

In addition, a virtual closed curve having the first center point CP1 as the center is referred to as a third line L3. A virtual closed curve having the first center point CP1 as the center and surrounding (e.g., around a periphery of) the third line L3 is referred to as a fourth line L4.

In the first structure, the first line L1 may surround (e.g., around a periphery of) the third line L3, the fourth line L4 may surround (e.g., around a periphery of) the first line L1, and the second line L2 may surround (e.g., around a periphery of) the fourth line L4.

In the first structure, each of the first line L1, the second line L2, the third line L3, and the fourth line L4 may have a symmetrical or substantially symmetrical shape with respect to the first center line CL1 and the second center line CL2. In the first structure, at least one of the first line L1, the second line L2, the third line L3, and/or the fourth line L4 may be circular. For example, as shown in FIG. 5A, in the first structure, each of the first line L1, the second line L2, the third line L3, and the fourth line L4 may be circular. However, the present disclosure is not limited thereto, and the shape of the first line L1, the second line L2, the third line L3, and the fourth line L4 may be variously modified as needed or desired. For example, in the first structure, the shape of each of the first line L1, the second line L2, the third line L3, and the fourth line L4 may be elliptical.

A plurality of light-emitting diodes LED may be provided. The plurality of light-emitting diodes LED may be arranged symmetrically or substantially symmetrically with respect to the first center line CL1 and the second center line CL2. For example, the plurality of light-emitting diodes LED may include a plurality of first light-emitting diodes LED1 and a plurality of second light-emitting diodes LED2.

The plurality of first light-emitting diodes LED1 may be arranged along the first line L1. In other words, the center of each of the plurality of first light-emitting diodes LED1 may be disposed on the first line L1. Thus, the plurality of first light-emitting diodes LED1 may surround (e.g., around a periphery of) the first center point CP1. Spaces between the plurality of first light-emitting diodes LED1 may be uniform or substantially uniform.

The plurality of second light-emitting diodes LED2 may be arranged along the second line L2. In other words, the center of each of the plurality of second light-emitting diodes LED2 may be disposed on the second line L2. Thus, the plurality of second light-emitting diodes LED2 may surround (e.g., around a periphery of) the first center point CP1. Spaces between the plurality of second light-emitting diodes LEDs2 may be uniform or substantially uniform. Because the second line L2 surrounds (e.g., around a periphery of) the first line L1, the length of the circumference of the second line L2 may be greater than the length of that of the first line L1. Accordingly, the number of the plurality of second light-emitting diodes LED2 may be greater than the number of the plurality of first light-emitting diodes LED1.

In the first structure, a first distance d1, which is a distance from the first center point CP1 to the first line L1, may be greater than a second distance d2, which is a distance from the first line L1 to the second line L2. In this case, the first distance d1 may be a distance between the first center point CP1 and an intersection or crossing ISP1 between the first center line CL1 and the first line L1. In addition, the second distance d2 may be a distance between the intersection or crossing ISP1 between the first center line CL1 and the first line L1 and an intersection or crossing ISP2 between the first center line CL1 and the second line L2.

The cover frame 131 of the cover layer 130 may be disposed on the light-emitting diode LED. The plurality of cover openings OP130 may overlap with the plurality of light-emitting diodes LED. The number of the plurality of cover openings OP130 may be the same as the number of the plurality of light-emitting diodes LED, and one light-emitting diode LED may correspond to one cover opening OP130.

In a plan view, the size of each of the plurality of cover openings OP130 may be greater than the size of each of the plurality of light-emitting diodes LED. In a plan view, the size of any one of the plurality of cover openings OP130 may be greater than a sum of the sizes of the first sub light-emitting diode LEDs1, the second sub light-emitting diode LEDs2, and the third sub light-emitting diode LEDs3 of any one light-emitting diode LED corresponding to the cover opening OP130. Thus, in a plan view, the cover frame 131 and the plurality of light-emitting diodes LED may not overlap with each other.

A plurality of cover openings OP130 of the cover layer 130 may be provided. The plurality of cover openings OP130 may be arranged symmetrically or substantially symmetrically with respect to the first center line CL1 and the second center line CL2. For example, the plurality of cover openings OP130 may include a plurality of first cover openings OP1301 and a plurality of second cover openings OP1302.

The plurality of first cover openings OP1301 may be arranged along the third line L3. In other words, the center of each of the plurality of first cover openings OP1301 may be disposed on the third line L3. Thus, the plurality of first cover openings OP1301 may surround (e.g., around a periphery of) the first center point CP1. Spaces between the plurality of first cover openings OP1301 may be uniform or substantially uniform.

The plurality of second cover openings OP1302 may be arranged along the fourth line L4. In other words, the center of each of the plurality of second cover openings OP1302 may be disposed on the fourth line L4. Thus, the plurality of second cover openings OP1302 may surround (e.g., around a periphery of) the first center point CP1. Spaces between the plurality of second cover openings OP1302 may be uniform or substantially uniform.

In the first structure, a third distance d3, which is a distance from the first center point CP1 to the third line L3, may be equal to or substantially equal to a fourth distance d4, which is a distance from the third line L3 to the fourth line L4. In this case, the third distance d3 may be a distance between the first center point CP1 and an intersection or crossing ISP3 between the first center line CL1 and the third line L3. In addition, the fourth distance d4 may be a distance between the intersection or crossing ISP3 between the first center line CL1 and the third line L3 and an intersection or crossing ISP4 between the first center line CL1 and the fourth line L4.

In the above-described structure, even if the first distance d1 is different from the second distance d2, because the cover opening OP130 is defined as the pixel PX and the third distance d3 is the same or substantially the same as the fourth distance d4, the plurality of pixels PX may be arranged uniformly or substantially uniformly.

FIG. 6A is a schematic plan view of the display device 1 according to an embodiment. FIG. 6B is a schematic cross-sectional view of the display device 1 according to an embodiment.

In more detail, FIG. 6A is an enlarged view of the region B of FIG. 4, and FIG. 6B is a cross-sectional view of the display device 1 taken along the line VI-VI′ of FIG. 6A.

In FIGS. 6A and 6B, the same reference numbers as those described above with reference to FIGS. 5A and 5B are used to denote the same or substantially the same members, and thus, redundant description thereof may not be repeated.

Referring to FIGS. 6A and 6B, the display device 1 may include the display panel 10 and the driver 400. The display panel 10 may include the substrate 100, the circuit element layer 110, the light-emitting diode LED, the bank layer 120, the cover layer 130, and the encapsulation layer 300.

The substrate 100 may have a flexible, rollable, and/or bendable characteristic. The circuit element layer 110 may be disposed on the substrate 100. The circuit element layer 110 may include the pixel driving circuit portion PC. For example, the pixel driving circuit portion PC may include a first pixel driving circuit portion PC1, a second pixel driving circuit portion PC2, and a third pixel driving circuit portion PC3 that are spaced apart from one another. The bank layer 120 may be disposed on the circuit element layer 110.

The light-emitting diode LED may be disposed on the circuit element layer 110, and may be electrically connected to the pixel driving circuit portion PC. The light-emitting diode LED may include the plurality of sub light-emitting diodes LEDs1, LEDs2, and LEDs3. For example, the light-emitting diode LED may include the first sub light-emitting diode LEDs1, the second sub light-emitting diode LEDs2, and the third sub light-emitting diode LEDs3.

The first sub light-emitting diode LEDs1 may include a first pixel electrode 211, a first emission layer 212, a common electrode 201, a first functional layer 202, and a second functional layer 203. The second sub light-emitting diode LEDs2 may include a second pixel electrode 221, a second emission layer 222, the common electrode 201, the first functional layer 202, and the second functional layer 203. The third sub light-emitting diode LEDs3 may include a third pixel electrode 231, a third emission layer 232, the common electrode 201, the first functional layer 202, and the second functional layer 203. The bank layer 120 may be disposed on the first to third pixel electrodes 211, 221, and 231. The bank layer 120 may include a cover portion 121 and a bank opening OP120.

The cover layer 130 may be disposed on the substrate 100. The cover layer 130 may be disposed on the common electrode 201 of the light-emitting diode LED. The cover layer 130 may include the cover frame 131, the support 132, and the cover opening OP130.

The cover frame 131 may be disposed on the substrate 100, and may be spaced apart from the common electrode 201. The cover frame 131 may include an opaque material. For example, the cover frame 131 may include at least one of a thermoplastic polyurethane (TPU), a thermoplastic polyethylene (TPE), and/or a silicon rubber material.

The support 132 may support the cover frame 131 from the substrate 100. For example, at least a portion of the support 132 may be arranged in the non-display area NDA (e.g., refer to FIG. 4), and may support the cover frame 131. A side of the support 132 may be fixed to the common electrode 201, and another side (e.g., an opposite side) of the support 132 may be fixed to the cover frame 131. The support 132 may include the same material as that of the cover frame 131. For example, the support 132 may include at least one of TPU, TPE, and/or a silicon rubber material. The support 132 may be formed integrally with the cover frame 131.

The cover opening OP130 may be disposed on the cover frame 131. The cover opening OP130 may pass through the cover frame 131. The cover opening OP130 may overlap withy the light-emitting diode LED. For example, one cover opening OP130 may overlap with the first sub light-emitting diode LEDs1, the second sub light-emitting diode LEDs2, and the third sub light-emitting diode LEDs3. The light-emitting diode LED may be exposed to the outside of the cover frame 131 by the cover opening OP130. Light emitted from the light-emitting diode LED may be displayed externally through the cover opening OP130. Thus, the light-emitting diode LED may be defined as the pixel PX.

The encapsulation layer 300 may be disposed on the substrate 100. The encapsulation layer 300 may be disposed on the cover layer 130. The encapsulation layer 300 may be supported by the cover layer 130. The encapsulation layer 300 may include at least one inorganic layer and at least one organic layer. For example, the encapsulation layer 300 may include a first inorganic encapsulation layer 310, an organic encapsulation layer 320, and a second inorganic encapsulation layer 330 that are sequentially stacked, but the present disclosure is not limited thereto, and the encapsulation layer 300 may include various suitable configurations.

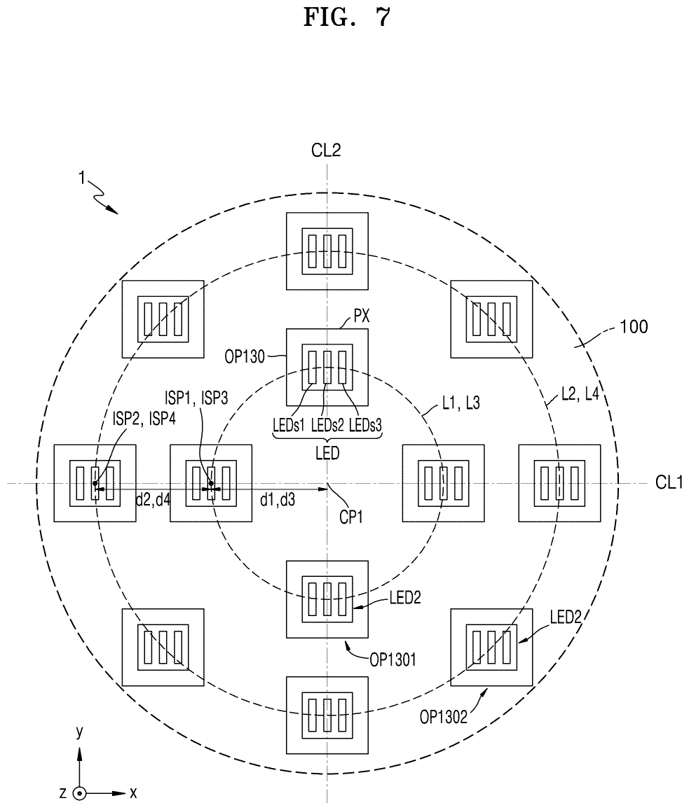

FIG. 7 is a schematic plan view of the display device 1 according to an embodiment.

In more detail, FIG. 7 is an enlarged view of the region A of FIG. 4. In FIG. 7, the same reference numbers as those described above with reference to FIG. 5A are used to denote the same or substantially the same members, and thus, redundant description thereof may not be repeated.

A second structure of the display device 1 is described in more detail hereinafter with reference to FIGS. 4 and 7. The second structure of the display device 1 may be a structure that is radially stretched from the first structure of the display device 1. In other words, the display device 1 may be converted between the first structure shown in FIG. 5A and the second structure shown in FIG. 7.

The stretchability of the substrate 100 may vary depending on the position. The stretchability of the substrate 100 may be increased as the substrate 100 becomes farther from the first center point CP1. In other words, the stretchability of the substrate 100 may be the least in the first center point CP1.

However, in the second structure, the shape of each of the first line L1, the second line L2, the third line L3, and the fourth line L4 may correspond to those of the first structure. In the second structure, each of the first line L1, the second line L2, the third line L3, and the fourth line L4 may have a symmetrical or substantially symmetrical shape with respect to the first center line CL1 and the second center line CL2. In the second structure, at least one of the first line L1, the second line L2, the third line L3, and/or the fourth line L4 may be circular. For example, as shown in FIG. 7, in the second structure, each of the first line L1, the second line L2, the third line L3, and the fourth line L4 may be circular. However, the present disclosure is not limited thereto, and the shape of the first line L1, the second line L2, the third line L3, and the fourth line L4 may be variously modified as needed or desired. For example, in the second structure, the shape of the first line L1, the second line L2, the third line L3, and the fourth line L4 may each be elliptical.

As the substrate 100 is stretched due to the display device 1 being converted from the first structure to the second structure, the first distance d1 and the second distance d2 may each be increased. In other words, in the second structure, the first distance d1 and the second distance d2 may each become greater than those in the first structure. However, because the stretchability of the substrate 100 is increased as the substrate 100 becomes farther from the first center point CP1, an increase rate of the second distance d2 may be greater than that of the first distance d1 when the display device 1 is converted from the first structure to the second structure.

Accordingly, the first distance d1 may be greater than the second distance d2 in the first structure, but a difference between the first distance d1 and the second distance d2 may be decreased as the display device 1 is converted from the first structure to the second structure. In other words, a difference between the distance between the first center point CP1 and the first line L1 and the distance between the first line L1 and the second line L2 may be less in the second structure than that in the first structure. For example, in the second structure, the first distance d1 and the second distance d2 may be the same or substantially the same as each other. In other words, the distance between the first center point CP1 and the first line L1 and the distance between the first line L1 and the second line L2 may be the same or substantially the same as each other.

A modulus of the cover frame 131 may be less than a modulus of the substrate 100. Therefore, the stretchability of the cover frame 131 according to the arrangement thereof may be uniform or substantially uniform when compared to that of the substrate 100.

As the cover frame 131 is stretched due to the display device 1 being converted from the first structure to the second structure, the third distance d3 and the fourth distance d4 may each be increased. In other words, in the second structure, the first distance d1 and the fourth distance d4 may each become greater than those in the first structure. However, because the stretchability of the cover frame 131 is maintained or substantially maintained constantly as the cover frame 131 becomes farther from the first center point CP1, the increase rate of the third distance d3 and the fourth distance d4 may be the same or substantially the same when the display device 1 is converted from the first structure to the second structure.

Accordingly, the third distance d3 may be the same or substantially the same as the fourth distance d4 in the first structure, and the third distance d3 may continue to be the same or substantially the same as the fourth distance d4 even when the display device 1 is converted from the first structure to the second structure. In other words, in the second structure, the distance between the first center point CP1 and the third line L3 and the distance between the third line L3 and the fourth line L4 may be the same or substantially the same as each other.

In the second structure, the first line L1 and the third line L3 may overlap with each other. In addition, in the second structure, the second line L2 and the fourth line L4 may overlap with each other. Accordingly, in the second structure, the center of the plurality of light-emitting diodes may be the same or substantially the same as the center of the plurality of cover openings OP130.

According to the structure described above with reference to FIGS. 5A and 7, the arrangement of each of the plurality of light-emitting diodes and the plurality of cover openings OP130 may be uniform or substantially uniform in the second structure. In addition, in the second structure, the center of the plurality of light-emitting diodes may be the same or substantially the same as the center of the plurality of cover openings OP130. In other words, even if the display device 1 is stretched, the uneven stretchability of the substrate 100 may be compensated for.

In some embodiments, the modulus of the cover frame 131 may be greater than the modulus of the substrate 100.

In the present embodiment, in the first structure, the first distance d1, which is the distance from the first center point CP1 to the first line L1, may be the same or substantially the same as the second distance d2, which is the distance from the first line L1 to the second line L2. In this case, the first distance d1 may be the distance between the first center point CP1 and the intersection or crossing ISP1 between the first center line CL1 and the first line L1. In addition, the second distance d2 may be the distance between the intersection or crossing ISP1 between the first center line CL1 and the first line L1 and the intersection or crossing ISP2 between the first center line CL1 and the second line L2.

In addition, in the first structure, the third distance d3, which is a distance from the first center point CP1 to the third line L3, may be greater than the fourth distance d4, which is the distance from the third line L3 to the fourth line L4. In this case, the third distance d3 may be the distance between the first center point CP1 and the intersection or crossing ISP3 between the first center line CL1 and the third line L3. In addition, the fourth distance d4 may be the distance between the intersection or crossing ISP3 between the first center line CL1 and the third line L3 and the intersection or crossing ISP4 between the first center line CL1 and the fourth line L4.

Accordingly, in the second structure, the arrangement of each of the plurality of light-emitting diodes and the plurality of cover openings OP130 may be uniform or substantially uniform. In addition, in the second structure, the center of the plurality of light-emitting diodes may be the same or substantially the same as the center of the plurality of cover openings OP130. In other words, even if the display device 1 is stretched, the uneven stretchability of the substrate 100 may be compensated for.

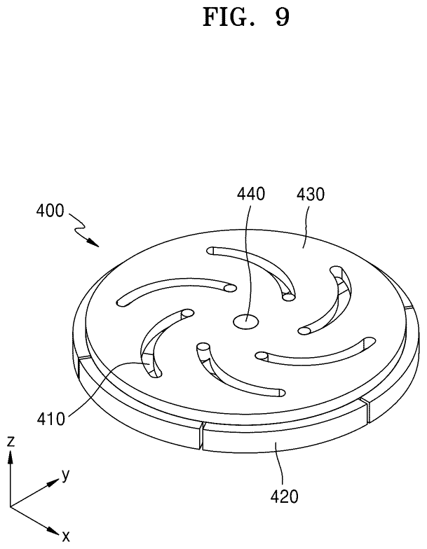

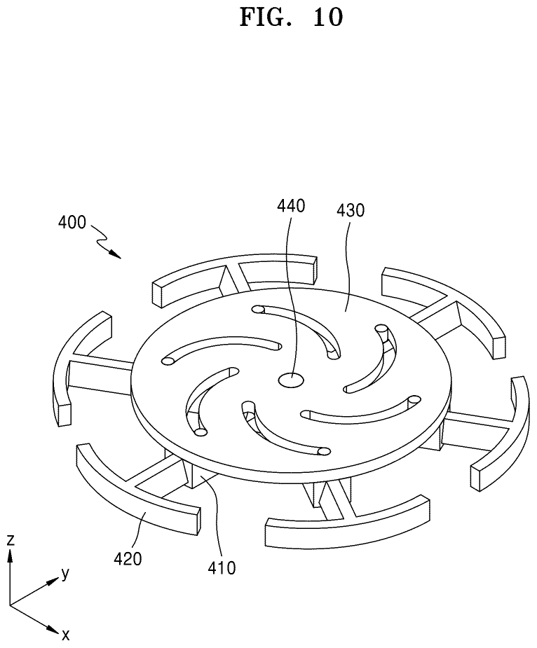

FIG. 8 is a schematic exploded view of the driver 400 according to an embodiment. FIGS. 9 and 10 are schematic perspective views of the driver 400 according to an embodiment.

Referring to FIGS. 8 to 10, the driver 400 may have an expanding pulley structure. The driver 400 may include a guide portion 410, an arm portion 420, a rotator 430, and a power generator 440.

The guide portion 410 may include a guide frame 411 and a guide groove 412. The guide frame 411 may form an appearance of the guide portion 410. A plurality of the guide grooves 412 may be provided, and the plurality of guide grooves 412 may be radially arranged along a circumferential direction of the guide frame 411. The plurality of guide grooves 412 may each extend in a direction outside the radius from the center of the guide frame 411. The guide groove 412 may be arranged on a plane defined in the first direction (e.g., the x direction and/or the −x direction) and the second direction (e.g., the y and/or the −y direction).

A plurality of the arm portions 420 may be provided corresponding to the number of guide grooves 412. The plurality of arm portions 420 may be arranged radially along the circumferential direction of the guide portion 410, so as to be connected to the guide portion 410. Each of the plurality of arm portions 420 may include an arm frame 421 and a protrusion 422.

At least a portion of the arm frame 421 may be accommodated in the guide groove 412. At least a portion of the arm frame 421 may have a shape corresponding to the guide groove 412. Because the guide groove 412 includes a longitudinal direction, the arm frame 421 accommodated in the guide groove 412 may be linearly moved. In other words, the arm frame 421 may move radially in a linear manner towards a direction away from or closer to the center of the guide frame 411.

The protrusion 422 may be fixed to the arm frame 421. The protrusion 422 may protrude toward the third direction (e.g., the z direction) from the arm frame 421. The protrusion 422 may have a cylindrical shape. In other words, in a plan view, the protrusion 422 may have a circular shape.

The rotator 430 may be connected to the arm portion 420. The rotator 430 may include a rotation frame 431 and a rotation opening 432. The rotation frame 431 may form an appearance of the rotator 430. The rotation frame 431 may have a disc shape.

A plurality of the rotation openings 432 may be provided to correspond to the number of protrusions 422, and may be disposed at (e.g., in or on) the rotation frame 431. The plurality of rotation openings 432 may be arranged radially with respect to the center of the rotation frame 431. The plurality of rotation openings 432 may be arranged in a spiral. For example, as shown in FIGS. 8 to 10, each of the plurality of rotation openings 432 may be distanced away from the center of the rotation frame 431 along an anti-clockwise direction with respect to the center of the rotation frame 431. As another example, unlike the illustrations of FIGS. 8 to 10, each of the plurality of rotation openings 432 may be distanced away from the center of the rotation frame 431 along a clockwise direction with respect to the center of the rotation frame 431.

The plurality of rotation openings 432 may have a shape corresponding to the plurality of protrusions 422. The plurality of protrusions 422 may be accommodated in the plurality of rotation openings 432. One rotation opening 432 may accommodate one protrusion 422 corresponding thereto.

The power generator 440 may generate power to move the guide portion 410 relative to the rotator 430. The power generator 440 may connect the center of the guide frame 411 to the center of the rotation frame 431. For example, the power generator 440 may include a rotation motor. Therefore, the rotator 430 may be rotated with respect to the guide portion 410.

Therefore, as the power generator 440 rotates the rotator 430 with respect to the guide portion 410, the driver 400 may be converted between a first form shown in FIG. 9 and a second form shown in FIG. 10.

Referring to FIGS. 3 to 10, the driver 400 may be connected to the display panel. The driver 400 may be fixed to one side of the substrate 100. For example, the arm frame 421 of the driver 400 may be fixed to the outside of the display panel.

For example, an adhesive member, such as a pressure sensitive adhesive (PSA), may fix the driver 400 to the display panel. However, the present disclosure is not limited thereto, and a separate adhesive film may be interposed between the display panel and the driver 400 so as to fix the display panel to the driver 400. The driver 400 may be configured to expand or reduce (e.g., relax or compress) the substrate 100 radially. For example, as the driver 400 is converted from the first form to the second form, the display device 1 may be converted from the first structure to the second structure as the substrate 100 is radially stretched. In addition, as the driver 400 is converted from the second form to the first form, the display device 1 may be converted from the second structure to the first structure as the substrate 100 is radially reduced (e.g., radially relaxed or compressed).

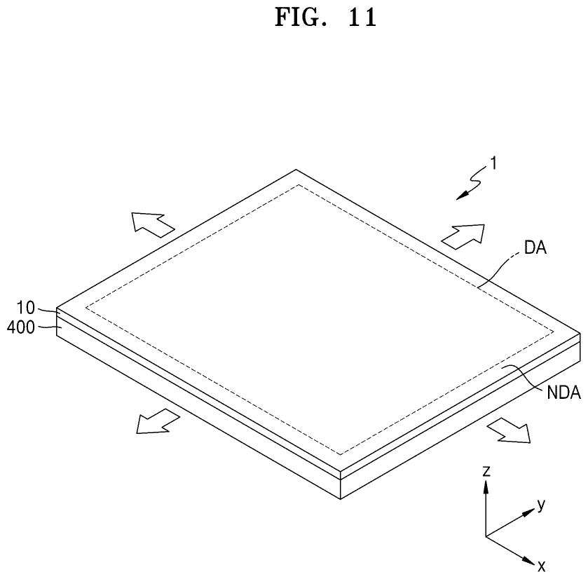

FIG. 11 is a perspective view showing a state in which the display device 1 of FIG. 1 is stretched radially.

The display device 1 may be stretched radially by an external object or an external force of the user. For example, the display device 1 may be quadrangular, and may be stretched in a diameter direction (e.g., in a perimeter direction) from the center.

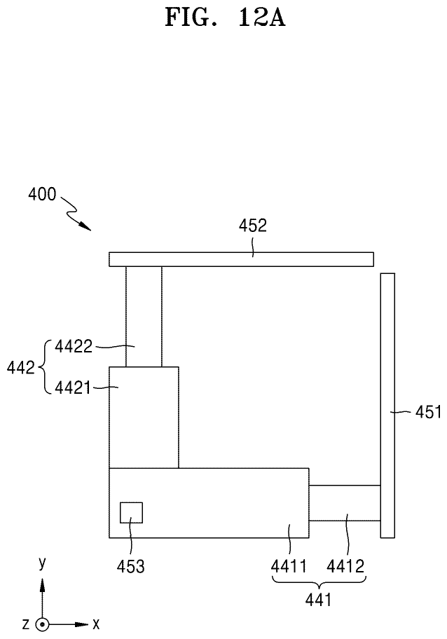

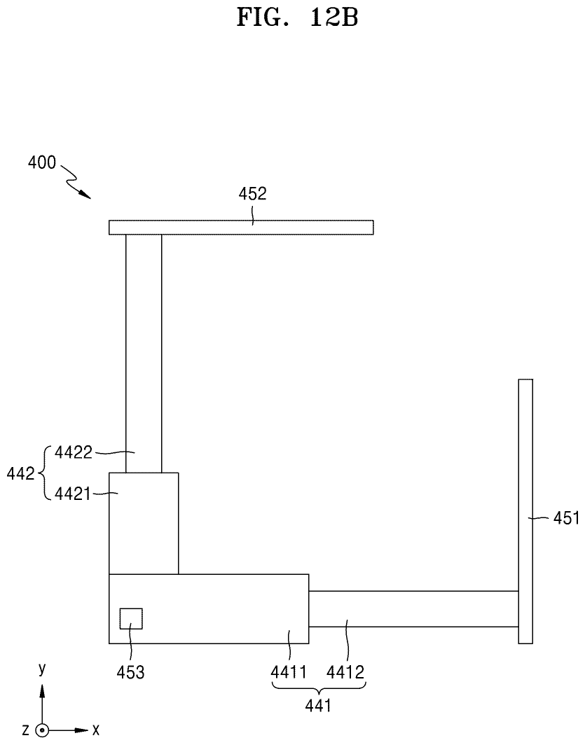

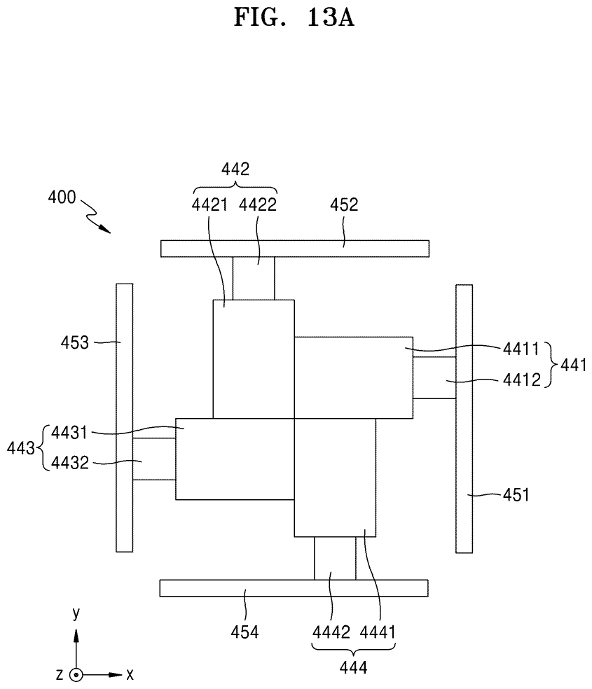

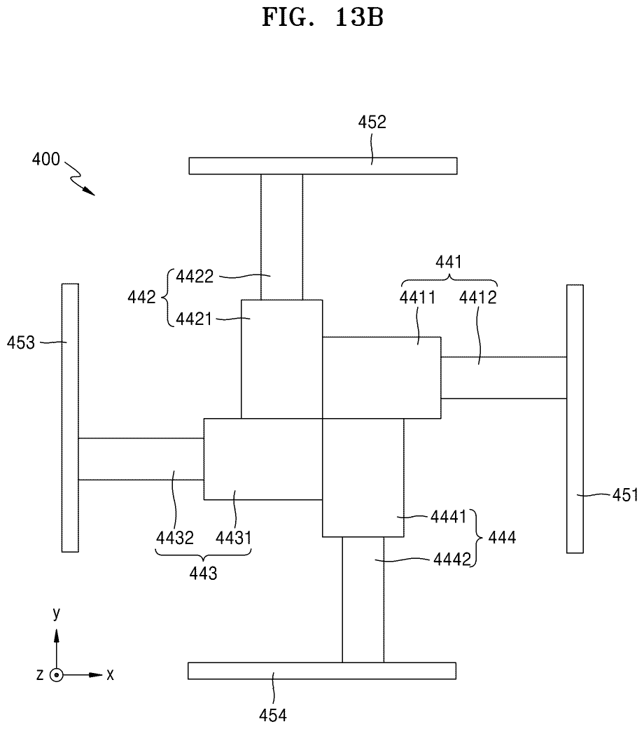

The display device 1 may include a display panel 10 and a driver 400. The display panel 10 may include the display area DA and the non-display area NDA described above with reference to FIG. 1. In an embodiment, the display area DA and/or the non-display area NDA may be radially stretched or reduced. The driver 400 may be fixed to one side of the display panel 10, and may provide a driving force to the display panel 10, such that the display panel 10 is stretched or reduced. The driver 400 is described in more detail below with reference to FIGS. 12A to 13B.

FIGS. 12A and 12B are schematic plan views of the driver 400 according to an embodiment.

Referring to FIGS. 12A and 12B, the driver 400 may include a first power generator 441, a second power generator 442, a first contact portion 451, a second contact portion 452, and a fixing portion 453.

The first power generator 441 may generate power for a linear movement of the first contact portion 451. The first power generator 441 may include a 1^{st}-1 portion 4411 and a 1^{st}-2 portion 4412. The 1^{st}-1 portion 4411 and the 1^{st}-2 portion 4412 may be connected to each other. The 1^{st}-1 portion 4411 may move linearly relative to the 1^{st}-2 portion 4412. For example, the first power generator 441 may include a linear motor.

The second power generator 442 may generate power for a linear movement of the second contact portion 452. The second power generator 442 may include a 2^{nd}-1 portion 4421 and a 2^{nd}-2 portion 4422. The 2^{nd}-1 portion 4421 and the 2^{nd}-2 portion 4422 may be connected to each other. The 2^{nd}-1 portion 4421 may move linearly relative to the 2^{nd}-2 portion 4422. For example, the second power generator 442 may include a linear motor.

The first power generator 441 and the second power generator 442 may be fixed to each other. In more detail, the 1^{st}-1 portion 4411 and the 2^{nd}-1 portion 4421 may be fixed to each other. The direction of the power generated by the first power generator 441 and the direction of the power generated by the second power generator 442 may cross each other. For example, the first power generator 441 may generate power in the first direction (e.g., the x direction or the −x direction) and the second power generator 442 may generate power in the second direction (e.g., the y direction or the −y direction). In the above-described structure, the 1^{st}-2 portion 4412 and the 2^{nd}-2 portion 4422 may move linearly in directions crossing each other. For example, the 1^{st}-2 portion 4412 may move in the first direction (e.g., the x direction or the −x direction) with respect to the 1^{st}-1 portion 4411, and the 2^{nd}-2 portion 4422 may move in the second direction (e.g., the y direction or the −y direction) with respect to the 2^{nd}-1 portion 4421.

Therefore, as the first power generator 441 moves the first contact portion 451 and the second power generator 442 moves the second contact portion 452, the driver 400 may be converted between the first form shown in FIG. 12A and the second form shown in FIG. 12B.

The first contact portion 451 may be fixed to the first power generator 441. In more detail, the first contact portion 451 may be fixed to the 1^{st}-2 portion 4412. Therefore, the first contact portion 451 may move linearly with respect to the 1^{st}-1 portion 4411 in the first direction (e.g., the x direction or the −x direction). The first contact portion 451 may extend in the second direction (e.g., the y direction or the −y direction).

The second contact portion 452 may be fixed to the second power generator 442. In more detail, the second contact portion 452 may be fixed to the 2^{nd}-2 portion 4422. Therefore, the second contact portion 452 may move linearly with respect to the 2^{nd}-1 portion 4421 in the second direction (e.g., the y direction or the −y direction). The second contact portion 452 may extend in the first direction (e.g., the x direction or the −x direction).

The fixing portion 453 may be fixed to at least one of the first power generator 441 and/or the second power generator 442. In more detail, the fixing portion 453 may be fixed to at least one of the 1^{st}-1 portion 4411 and/or the 1^{st}-2 portion 4412. For example, as shown in FIGS. 12A and 12B, the fixing portion 453 may be fixed to the 1^{st}-1 portion 4411.

Referring to FIGS. 1 to 7 and FIGS. 11 to 12B, the driver 400 may be connected to the display panel 10. The driver 400 may be fixed to one side of the substrate 100. For example, the first contact portion 451, the second contact portion 452, and the fixing portion 453 of the driver 400 may be fixed to the outside of the display panel 10.

FIGS. 13A and 13B are schematic plan views of the driver 400 according to an embodiment.

Referring to FIGS. 13A and 13B, the driver 400 may include the first power generator 441, the second power generator 442, a third power generator 443, a fourth power generator 444, the first contact portion 451, the second contact portion 452, a third contact portion 453, and a fourth contact portion 454.

The first power generator 441 may generate power for a linear movement of the first contact portion 451. The first power generator 441 may include the 1^{st}-1 portion 4411 and the 1^{st}-2 portion 4412. The 1^{st}-1 portion 4411 and the 1^{st}-2 portion 4412 may be connected to each other. The 1^{st}-1 portion 4411 may move linearly relative to the 1^{st}-2 portion 4412. For example, the first power generator 441 may include a linear motor.

The second power generator 442 may generate power for a linear movement of the second contact portion 452. The second power generator 442 may include the 2^{nd}-1 portion 4421 and the 2^{nd}-2 portion 4422. The 2^{nd}-1 portion 4421 and the 2^{nd}-2 portion 4422 may be connected to each other. The 2^{nd}-1 portion 4421 may move linearly relative to the 2^{nd}-2 portion 4422. For example, the second power generator 442 may include a linear motor.

The third power generator 443 may generate power for a linear movement of the third contact portion 453. The third power generator 443 may include a 3^{rd}-1 portion 4431 and a 3^{rd}-2 portion 4432. The 3^{rd}-1 portion 4431 and the 3^{rd}-2 portion 4432 may be connected to each other. The 3^{rd}-1 portion 4431 may move linearly relative to the 3^{rd}-2 portion 4432. For example, the third power generator 443 may include a linear motor.

The fourth power generator 444 may generate power for a linear movement of the fourth contact portion 454. The fourth power generator 444 may include a 4^{th}-1 portion 4411 and a 4^{th}-2 portion 4442. The 4^{th}-1 portion 4441 and the 4^{th}-2 portion 4442 may be connected to each other. The 4^{th}-1 portion 4441 may move linearly relative to the 4^{th}-2 portion 4442. For example, the fourth power generator 444 may include a linear motor.

The first power generator 441, the second power generator 442, the third power generator 443, and the fourth power generator 444 may be fixed to each other. In more detail, the 1^{st}-1 portion 4411, the 1^{st}-2 portion 4412, a 1^{st}-3 portion, and a 1^{st}-4 portion may be fixed to each other.

The direction of the power generated by the first power generator 441 and the direction of the power generated by the second power generator 442 may cross each other. The direction of the power generated by the second power generator 442 and the direction of the power generated by the third power generator 443 may cross each other. The direction of the power generated by the third power generator 443 and the direction of the power generated by the fourth power generator 444 may cross each other. The direction of the power generated by the fourth power generator 444 and the direction of the power generated by the first power generator 441 may cross each other.

The direction of the power generated by the first power generator 441 and the direction of the power generated by the third power generator 443 may be opposite to each other. The direction of the power generated by the second power generator 441 and the direction of the power generated by the fourth power generator 444 may be opposite to each other.

For example, the first power generator 441 may generate power in the first direction (e.g., the x direction), the second power generator 442 may generate power in the second direction (e.g., the y direction), the third power generator 443 may generate power in the first direction (e.g., the −x direction), and the fourth power generator 444 may generate power in the second direction (e.g., the −y direction).

In the above-described structure, the 1^{st}-2 portion 4412 and the 2^{nd}-2 portion 4422 may linearly move in directions crossing each other, the 2^{nd}-2 portion 4422 and the 3^{rd}-2 portion 4432 may linearly move in directions crossing each other, the 3^{rd}-2 portion 4432 and the 4^{th}-2 portion 4442 may linearly move in directions crossing each other, and the 4^{th}-2 portion 4442 and the 1^{st}-2 portion 4412 may linearly move in directions crossing each other.

In addition, the 1^{st}-2 portion 4412 and the 3^{rd}-2 portion 4432 may linearly move in directions opposite to each other, and the 2^{nd}-2 portion 4422 and the 4^{th}-2 portion 4442 may linearly move in directions opposite to each other.

For example, the 1^{st}-2 portion 4412 may move in the first direction (e.g., the x direction) with respect to the 1^{st}-1 portion 4411, the 2^{nd}-2 portion 4422 may move in the second direction (e.g., the y direction) with respect to the 2^{nd}-1 portion 4421, the 3^{rd}-2 portion 4432 may move in the first direction (e.g., the −x direction) with respect to the 3^{rd}-1 portion 4431, and the 4^{th}-2 portion 4442 may move in the second direction (e.g., the −y direction) with respect to the 4^{th}-1 portion 4441.

Therefore, as the first power generator 441 moves the first contact portion 451, the second power generator 442 moves the second contact portion 452, the third power generator 443 moves the third contact portion 453, and the fourth power generator 444 moves the fourth contact portion 454, the driver 400 may be converted between the first form shown in FIG. 13A and the second form shown in FIG. 13B.

The first contact portion 451 may be fixed to the first power generator 441. In more detail, the first contact portion 451 may be fixed to the 1^{st}-2 portion 4412. Therefore, the first contact portion 451 may move linearly with respect to the 1^{st}-1 portion 4411 in the first direction (e.g., the x direction). The first contact portion 451 may extend in the second direction (e.g., the y direction or the −y direction).

The second contact portion 452 may be fixed to the second power generator 442. In more detail, the second contact portion 452 may be fixed to the 2^{nd}-2 portion 4422. Therefore, the second contact portion 452 may move linearly with respect to the 2^{nd}-1 portion 4421 in the second direction (e.g., the y direction). The second contact portion 452 may extend in the first direction (e.g., the x direction or the −x direction).

The third contact portion 453 may be fixed to the third power generator 443. In more detail, the third contact portion 453 may be fixed to the 3^{rd}-2 portion 4432. Therefore, the third contact portion 453 may move linearly with respect to the 3^{rd}-1 portion 4431 in the first direction (e.g., the −x direction). The third contact portion 453 may extend in the second direction (e.g., the y direction or the −y direction).

The fourth contact portion 454 may be fixed to the fourth power generator 444. In more detail, the fourth contact portion 454 may be fixed to the 4^{th}-2 portion 4442. Therefore, the fourth contact portion 454 may move linearly with respect to the 4^{th}-1 portion 4441 in the second direction (e.g., the −y direction). The fourth contact portion 454 may extend in the first direction (e.g., the x direction or the −x direction).

Referring to FIGS. 1 to 7 and FIGS. 11 to 13B, the driver 400 may be connected to the display panel 10. The driver 400 may be fixed to one side of the substrate 100. For example, the first contact portion 451, the second contact portion 452, the third contact portion 453, and the fourth contact portion 454 of the driver 400 may be fixed to the outside of the display panel 10.

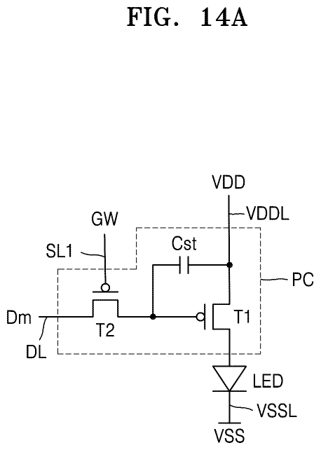

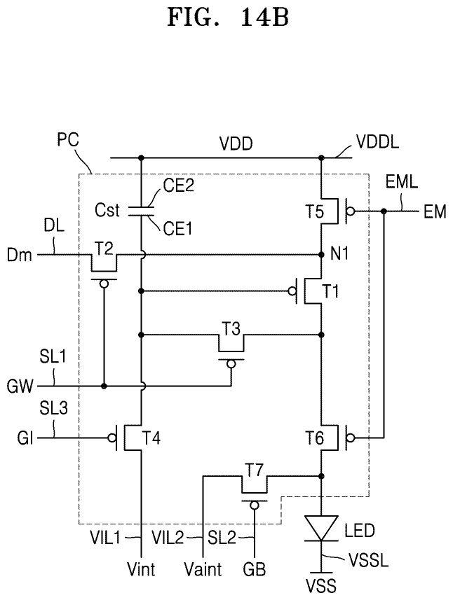

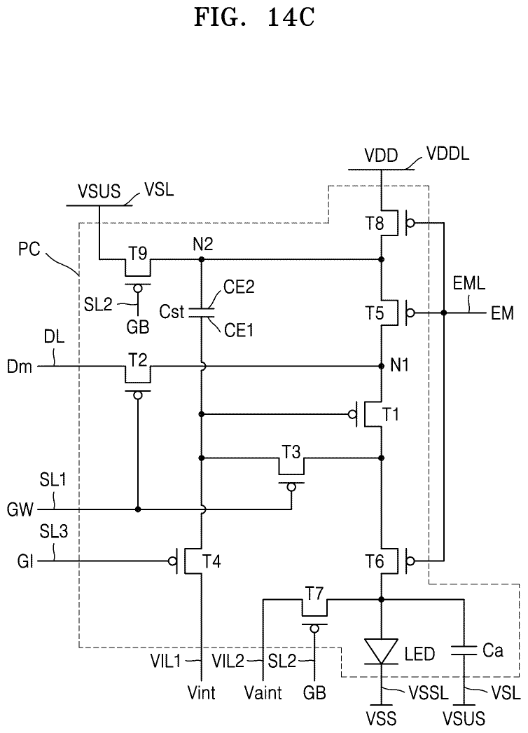

FIGS. 14A through 14C are equivalent circuit diagrams of a subpixel of the display device 1 according to one or more embodiments.

Referring to FIG. 14A, the light-emitting diode LED corresponding to the subpixel may be electrically connected to the pixel driving circuit portion PC. The pixel driving circuit portion PC may include a first transistor T1, a second transistor T2, and a storage capacitor Cst. The pixel driving circuit portion PC may be electrically connected to a signal line and a voltage line. The signal line may include a gate line, such as a first scan line SL1, and a data line DL, and the voltage line may include a first voltage line VDDL.

The second transistor T2 may be electrically connected to the first scan line SL1 and the data line DL. The first scan line SL1 may provide a first scan signal GW1 to a gate electrode of the second transistor T2. The second transistor T2 may transmit a data signal Dm input from the data line DL to the first transistor T1 according to the first scan signal GW1 input from the first scan line SL1.

The storage capacitor Cst may be electrically connected to the second transistor T2 and the first voltage line VDDL, and may store a voltage corresponding to a difference between a voltage received from the second transistor T2 and a first power voltage VDD supplied by the first voltage line VDDL.

The first transistor T1 is a driving transistor that may control a driving current flowing through the light-emitting diode LED. The first transistor T1 may be connected to the first voltage line VDDL and the storage capacitor CST. The first transistor T1 may control a driving current flowing from the first voltage line VDDL through the light-emitting diode LED in correspondence with a voltage value stored in the storage capacitor Cst. The light-emitting diode LED may emit light having a desired brightness (e.g., a certain or predetermined brightness) according to the driving current. The first electrode of the light-emitting diode LED may be electrically connected to the first transistor T1, and the second electrode may be electrically connected to a second voltage line VSSL for supplying a second power voltage VSS.

FIG. 14A shows that the pixel driving circuit portion PC includes two transistors and one storage capacitor. However, in some embodiments, the pixel driving circuit portion PC may include three or more transistors.

Referring to FIG. 14B, the pixel driving circuit portion PC may include the first transistor T1, the second transistor T2, a third transistor T3, a fourth transistor T4, a fifth transistor T5, a sixth transistor T6, a seventh transistor T7, and a storage capacitor Cst.

The pixel driving circuit portion PC may be electrically connected to signal lines and voltage lines. The signal lines may include a gate line, such as the first scan line SL1, a second scan line SL2, a third scan line SL3, a fourth scan line SL4, and an emission control line EML, and the data line DL. The voltage lines may include first and second initialization voltage lines VIL1 and VIL2, and the first voltage line VDDL.

The first voltage line VDDL may transmit the first power voltage VDD to the first transistor T1. The first initialization voltage line VIL1 may transmit a first initialization voltage Vint configured to initialize the first transistor T1 to the pixel driving circuit portion PC. The second initialization voltage line VIL2 may transmit a second initialization voltage Vaint configured to initialize the first electrode of the light-emitting diode LED to the pixel driving circuit portion PC.

The first transistor T1 may be electrically connected to the first voltage line VDDL via the fifth transistor T5, and may be electrically connected to the light-emitting diode LED via the sixth transistor T6. The first transistor T1 may act as a driving transistor, may receive the data signal Dm according to a switching operation of the second transistor T2, and may supply a driving current to the light-emitting diode LED.

The second transistor T2 is a data write transistor, and is electrically connected to the first scan line SL1 and the data line DL. The second transistor T2 is electrically connected to the first voltage line VDDL via the fifth transistor T5. The second transistor T2 is turned on according to the first scan signal GW received through the first scan line SL1, and performs a switching operation for transmitting the data signal Dm received via the data line DL to a first node N1.

The third transistor T3 is electrically connected to the first scan line SL1, and is electrically connected to the light-emitting diode LED via the sixth transistor T6. The third transistor T3 may be turned on in response to the first scan signal GW received through the first scan line SL1, and may diode-connect the first transistor T1.

The fourth transistor T4 is a first initialization transistor, and is electrically connected to the third scan line SL3 and the first initialization voltage line VIL1. The fourth transistor T4 is turned on according to a third scan signal GI received through the third scan line SL3, and transmits the first initialization voltage Vint from the first initialization voltage line VIL1 to the gate electrode of the first transistor T1, thereby initializing a voltage of the gate electrode of the first transistor T1. The third scan signal GI may correspond to the first scan signal of another pixel driving circuit portion PC arranged in a row preceding the pixel driving circuit portion PC corresponding to the third scan signal GI.

The fifth transistor T5 may be an operation control transistor, and the sixth transistor T6 may be an emission control transistor. The fifth transistor T5 and the sixth transistor T6 may be electrically connected to the emission control line EML, and may be turned on concurrently (e.g., at the same or substantially the same time) as each other according to an emission control signal EM received through the emission control line EML, thereby forming a current path through which the driving current may flow in the direction of the light-emitting diode LED from the first voltage line VDDL.

The seventh transistor T7 is a second initialization transistor, and may be electrically connected to the second scan line SL2, the second initialization voltage line VIL2, and the sixth transistor T6. The seventh transistor T7 is turned on according to the second scan signal GB received through the second scan line SL2, and transmits the second initialization voltage Vaint from the second initialization voltage line VIL2 to the first electrode of the light-emitting diode LED, thereby initializing the first electrode of the light-emitting diode LED.

The storage capacitor Cst includes a first electrode CE1 and a second electrode CE2. The first electrode CE1 is electrically connected to the gate electrode of the first transistor T1, and the second electrode CE2 is electrically connected to the first voltage line VDDL. The storage capacitor Cst may store and maintain a voltage corresponding to a difference between voltages of both ends (e.g., opposite ends) of the first voltage line VDDL and the gate electrode of the first transistor T1, thereby maintaining or substantially maintaining the voltage applied to the gate electrode of the first transistor T1.

Referring to FIG. 14C, the pixel driving circuit portion PC may include the first transistor T1, the second transistor T2, the third transistor T3, the fourth transistor T4, the fifth transistor T5, the sixth transistor T6, the seventh transistor T7, an eighth transistor T8, a ninth transistor T9, a storage capacitor Cst, and an auxiliary capacitor Ca.

The pixel driving circuit portion PC may be electrically connected to the signal lines and the voltage lines. The signal lines may include the gate line, such as the first scan line SL1, the second scan line SL2, the third scan line SL3, the fourth scan line SL4, and the emission control line EML, and the data line DL. The voltage lines may include first and second initialization voltage lines VIL1 and VIL2, a maintenance voltage line VSL, and the first voltage line VDDL.

The first voltage line VDDL may transmit the first power voltage VDD to the first transistor T1. The first initialization voltage line VIL1 may transmit the first initialization voltage Vint configured to initialize the first transistor T1 to the pixel driving circuit portion PC. The second initialization voltage line VIL2 may be transmit the second initialization voltage Vaint configured to initialize the first electrode of the light-emitting diode LED to the pixel driving circuit portion PC. In an initialization section and a data write section, the maintenance voltage line VSL may supply a maintenance voltage VSUS to a second node N2, such as to the second electrode CE2 of the storage capacitor Cst.

The first transistor T1 may be electrically connected to the first voltage line VDDL via the fifth transistor T5 and the eighth transistor T8, and may be electrically connected to the light-emitting diode LED via the sixth transistor T6. The first transistor T1 may act as a driving transistor, may receive the data signal Dm according to a switching operation of the second transistor T2, and may supply a driving current to the light-emitting diode LED.

The second transistor T2 is electrically connected to the first scan line SL1 and the data line DL, and is electrically connected to the first voltage line VDDL via the fifth transistor T5 and the eighth transistor T8. The second transistor T2 is turned on according to the first scan signal GW received through the first scan line SL1, and performs a switching operation for transmitting the data signal Dm received via the data line DL to the first node N1.

The third transistor T3 is electrically connected to the first scan line SL1, and is electrically connected to the light-emitting diode LED via the sixth transistor T6. The third transistor T3 may be turned on according to the first scan signal GW received through the first scan line SL1, and may diode-connect the first transistor T1, thereby compensating for a threshold voltage of the first transistor T1.

The fourth transistor T4 is electrically connected to the third scan line SL3 and the first initialization voltage line VIL1, may be turned on according to the third scan signal GI received through the third scan line SL3, and may transmit the first initialization voltage Vint from the first initialization voltage line VIL1 to the gate electrode of the first transistor T1, thereby initializing the voltage of the gate electrode of the first transistor T1. The third scan signal GI may correspond to the first scan signal of another pixel driving circuit portion PC arranged in a row preceding the pixel driving circuit portion PC corresponding to the third scan signal GI.

The fifth transistor T5, the sixth transistor T6, and the eighth transistor T8 may be electrically connected to the emission control line EML, and may be turned on concurrently (e.g., at the same or substantially the same time) as each other according to the emission control signal EM received through the emission control line EML, thereby forming a current path through which the driving current may flow in the direction of the light-emitting diode LED from the first voltage line VDDL.

The seventh transistor T7 is a second initialization transistor, and may be electrically connected to the second scan line SL2, the second initialization voltage line VIL2, and the sixth transistor T6. The seventh transistor T7 is turned on according to the second scan signal GB received through the second scan line SL2, and transmits the second initialization voltage Vaint from the second initialization voltage line VIL2 to the first electrode of the light-emitting diode LED, thereby initializing the first electrode of the light-emitting diode LED.

The ninth transistor T9 may be electrically connected to the second scan line SL2, the second electrode CE2 of the storage capacitor Cst, and the maintenance voltage line VSL. The ninth transistor T9 may be turned on according to the second scan signal GB received through the second scan line SL2, and may transmit the maintenance voltage VSUS to the second node N2, such as to the second electrode CE2 of the storage capacitor Cst, in the initialization section and the data write section.

The eighth transistor T8 and the ninth transistor T9 may each be electrically connected to the second node N2, such as to the second electrode CE2 of the storage capacitor Cst. In some embodiments, the eighth transistor T8 may be turned off and the ninth transistor T9 may be turned on in the initialization section and the data write section, and the eighth transistor T8 may be turned on and the ninth transistor T9 may be turned off in an emission section. Because the maintenance voltage VSUS is transmitted to the second node N2 in the initialization section and the data write section, a long range uniformity (LRU) of the brightness of the display device may be improved according to a voltage drop of the first voltage line VDDL.

The storage capacitor Cst includes the first electrode CE1 and the second electrode CE2. The first electrode CE1 is electrically connected to the gate electrode of the first transistor T1, and the second electrode CE2 is electrically connected to the eighth transistor T8 and the ninth transistor T9.

The auxiliary capacitor Ca may be electrically connected to the sixth transistor T6, the maintenance voltage line VSL, and the first electrode of the light-emitting diode LED. The auxiliary capacitor Ca stores and maintains or substantially maintains a voltage corresponding to a voltage difference between the first electrode of the light-emitting diode LED and the maintenance voltage line VSL while the seventh transistor T7 and the ninth transistor T9 are turned on, thereby preventing or substantially preventing a black luminance from being increased when the sixth transistor T6 is turned off.

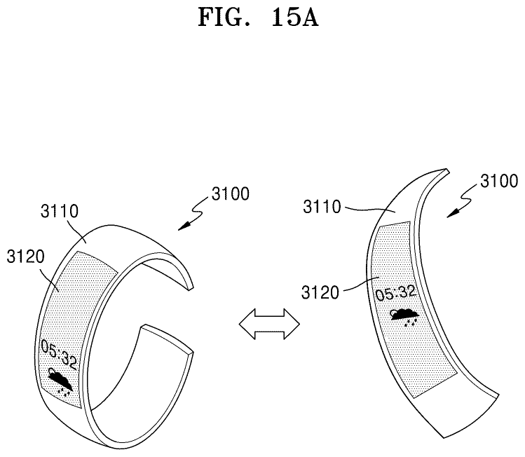

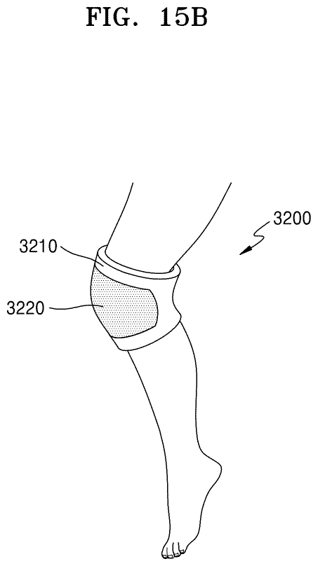

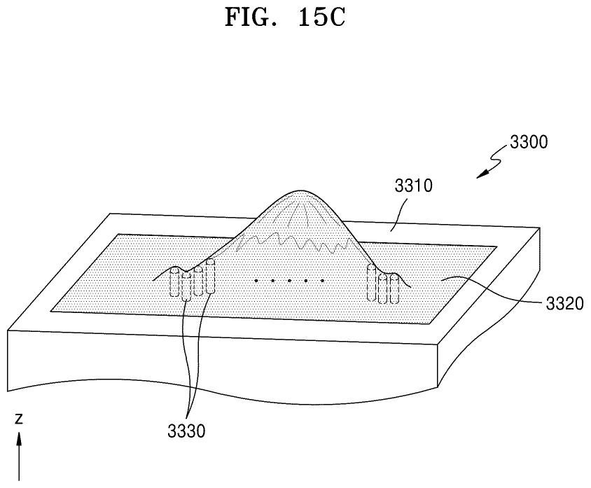

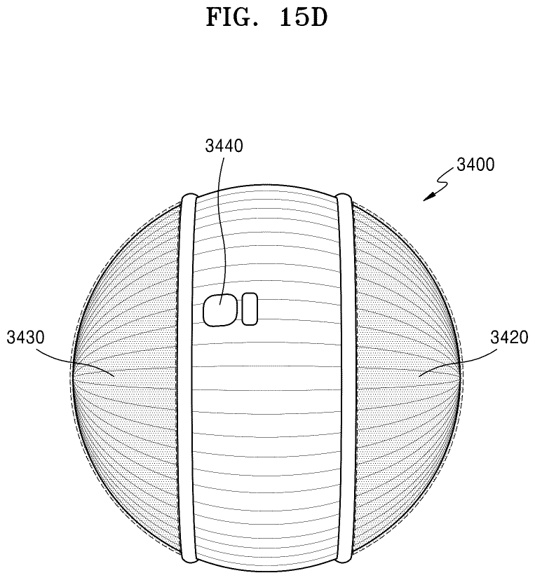

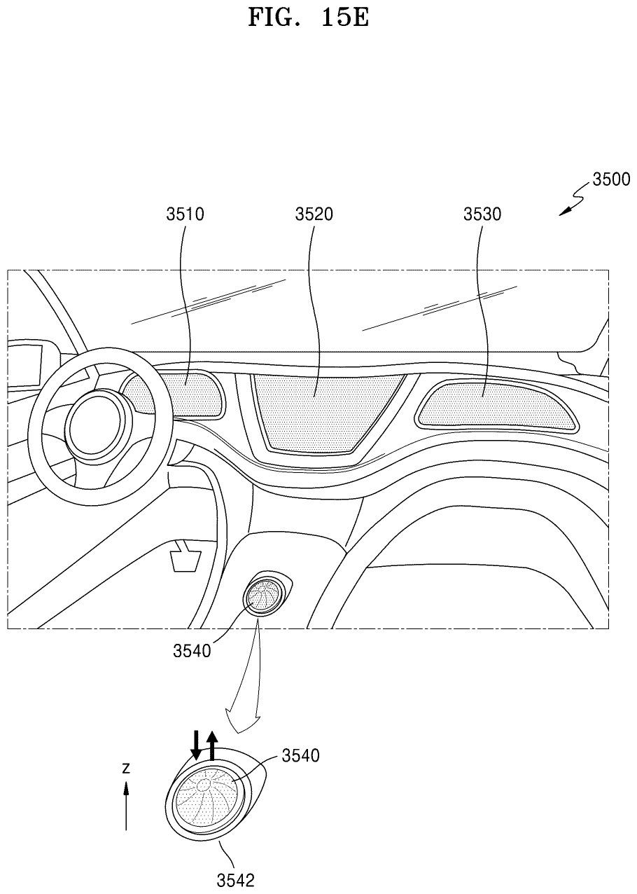

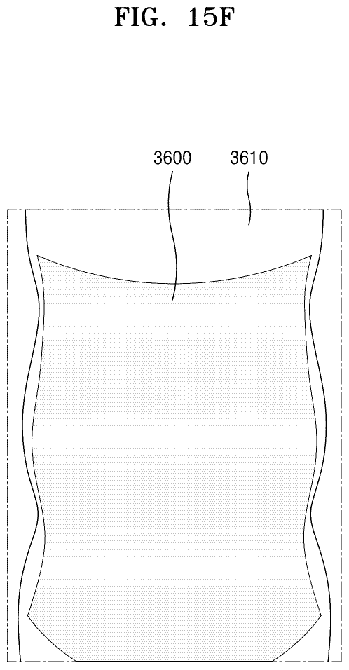

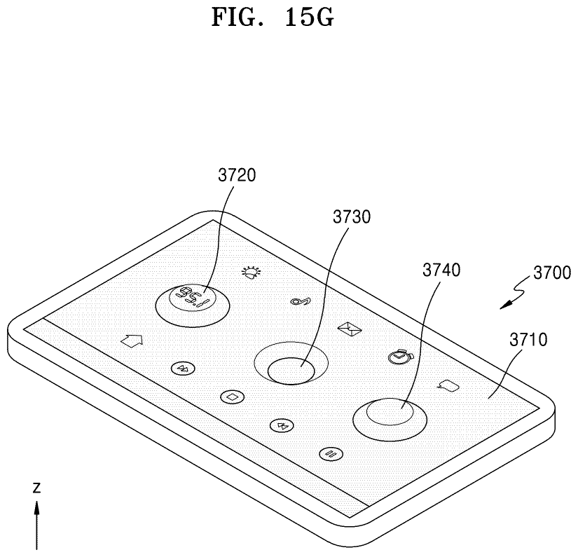

FIGS. 15A through 15G are schematic perspective views showing various embodiments of electronic equipment including a display device according to one or more embodiments.

Referring to FIG. 15A, the display device according to an embodiment may be used for wearable electronic equipment 3100 that may be worn on any suitable part of the body of the user. The wearable electronic equipment 3100 may include a body portion 3110, and a display portion 3120 included in the body portion 3110. The display device according to an embodiment may be used as the display portion 3120 of the wearable electronic equipment 3100. As shown in FIG. 15A, the wearable electronic equipment 3100 may be modified. In other words, a shape of the wearable electronic equipment 3100 may be modified. In an embodiment, the wearable electronic equipment 3100 may be used as a smartwatch or a smartphone according to the user's choice.

FIG. 15B illustrates medical electronic equipment 3200. In an embodiment, the medical electronic equipment 3200 may include a body portion 3210 and a light-emitting portion 3220. The display device according to an embodiment may be used as the light-emitting portion 3220 of the medical electronic equipment 3200. The light-emitting portion 3220 may emit light (e.g., infrared ray, visible light, and/or the like) of a desired wavelength band (e.g., a certain or predetermined wavelength band) to the body of a patient. In an embodiment, the body portion 3210 may have a stretchable fiber material, and may have a suitable structure that may be worn on the body of the user or the patient.

FIG. 15C shows educational electronic equipment 3300. In an embodiment, the educational electronic equipment may include a display portion 3320 included in a frame 3310. The display portion 3320 may use the display device according to the one or more embodiments. The display portion 3320 may provide an image, such as the sea with waves, a mountain covered with snow, or a volcano with lava flowing thereon, and the display portion 3320 may be stretched in the height direction (e.g., the z direction) to reflect the height of the waves, the mountains, or the volcanoes. In some embodiments, a portion of the display portion 3320 may three-dimensionally show a movement of lava by sequentially varying the height thereof according to the direction in which the lava flows. The educational electronic equipment 3300 may include a plurality of pins (e.g., stroke portions 3330) arranged on a rear surface of the display portion 3320, such that the display portion 3320 may be stretched in the height direction (e.g., the z direction). The pins 3330 may be implemented to move in the third direction (e.g., the z direction or the −z direction), such that the image expressed by the display portion 3320 has a three-dimensional height. FIG. 15C illustrates the educational electronic equipment 3300, but the usage thereof is not limited thereto, as long as it provides image information (e.g., predetermined image information).

FIGS. 15A to 15C illustrate electronic equipment of which the shape thereof may be modified, but the present disclosure is not limited thereto. As described in more detail below, the display device according to some embodiments may be used in electronic equipment of which an area that may express an image (e.g., a screen) thereof is fixed.

FIG. 15D shows a robot 3400 as the electronic equipment according to an embodiment. The robot 3400 may detect a movement or an object by using a camera portion 3440, and may display an image (e.g., a predetermined image) to a user through display portions 3420 and 3430. In some embodiments, because the display devices may be stretched in various suitable directions as described above, the display devices may be assembled to a body frame having a hemispherical shape, and thus, the robot 3400 may include hemispherical display portions 3420 and 3430.

FIG. 15E shows vehicle display equipment 3500 as the electronic equipment according to an embodiment. The vehicle display device 3500 may include a cluster 3510, a center information display (CID) 3520, and/or a passenger display 3530. Because the display device according to some embodiments may be stretched in various suitable directions, the display device may be used in the cluster 3510, CID 3520, and/or a co-driver or passenger display 3530 without being bounded by the shape of an inner frame of the vehicle.

FIG. 15E illustrates that each of the cluster 3510, the CID 3520, and/or the co-driver or passenger display 3530 is separated from each other, but the present disclosure is not limited thereto. In some embodiments, at least two selected from the cluster 3510, the CID 3520, and the co-driver display 3530 may be integrally connected to each other.

In some embodiments, the vehicle display device 3500 may include a button 3540 that may express an image (e.g., a predetermined image). Referring to the enlarged view in FIG. 15E, the hemispherical button 3540 may include an object 3542 that may be moved in the third direction (e.g., the z direction or the −z direction) to provide a feeling of a button, and a display device disposed on the object 3542. In some embodiments, when the object 3542 has a three-dimensionally round surface, the display device may also have a three-dimensionally round surface.

FIG. 15F illustrates that electronic equipment 3600 according to an embodiment may be used for advertising or an exhibition. In some embodiments, the electronic equipment 3600 for the advertising or the exhibition may be installed in a fixed structure 3610, such as a wall or a pillar. When the structure 3610 includes an uneven surface as shown in FIG. 15F, the electronic equipment 3600 for the advertising or the exhibition may be arranged along the uneven surface of the structure 3610. In some embodiments, the electronic equipment 3600 for the advertising or the exhibition may be installed in the structure 3610 by using a thermal-shrinking film and/or the like.

FIG. 15G shows a controller 3700 as the electronic equipment according to an embodiment. The controller 3700 may include an image-type button. For example, the controller 3700 may include first to third button areas 3720, 3730, and 3740, which are portions of a display portion 3710 protruding in the z direction or protruding in the −z direction (or being submerged in the z direction). In some embodiments, the first and third button areas 3720 and 3740 may protrude in the z direction, and the second button area 3730 may protrude in the −z direction (or may be submerged in the z direction).

The display device according to some embodiments described above may have improved visibility.

However, the present disclosure is not limited thereto.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a display area and a non-display area;
a substrate;
a plurality of light-emitting diodes on the substrate; and
a cover layer comprising:
a cover frame on the substrate and comprising an opaque material; and
a plurality of cover openings in the cover frame to overlap with the plurality of light-emitting diodes,
wherein the plurality of light-emitting diodes comprises:
a plurality of first light-emitting diodes located along a first line, the first line being a virtual closed curve having a first center point as a center; and
a plurality of second light-emitting diodes located along a second line, the second line being a virtual closed curve having the first center point as the center and surrounding around the first line, and
wherein the plurality of cover openings comprises:
a plurality of first cover openings located along a third line, the third line being a virtual closed curve having the first center point as the center; and
a plurality of second cover openings located along a fourth line, the fourth line being a virtual closed curve having the first center point as the center and surrounding around the third line.

2. The display device of claim 1, wherein a distance between the first center point and the first line is greater than a distance between the first line and the second line.

3. The display device of claim 1, wherein a distance between the first center point and the third line is equal to a distance between the third line and the fourth line.

4. The display device of claim 1, wherein:
the first line surrounds around the third line; and
the second line surrounds around the fourth line.

5. The display device of claim 1, wherein a modulus of the cover frame is less than a modulus of the substrate.

6. The display device of claim 1, wherein, in a plan view, a size of each of the plurality of cover openings is greater than a size of each of the plurality of light-emitting diodes.

7. The display device of claim 1, wherein the plurality of light-emitting diodes are symmetrically located with respect to a first center line and a second center line, the first center line being a virtual line passing through the first center point in a first direction, and the second center line being a virtual line passing through the first center point in a second direction crossing the first direction.

8. The display device of claim 1, wherein the plurality of cover openings are symmetrically located with respect to a first center line and a second center line, the first center line being a virtual line passing through the first center point in a first direction, and the second center line being a virtual line passing through the first center point in a second direction crossing the first direction.

9. The display device of claim 1, wherein at least one of the first line, the second line, the third line, or the fourth line is circular.

10. The display device of claim 1, wherein the cover frame comprises at least one of a thermoplastic polyurethane (TPU), a thermoplastic polyethylene (TPE), or a silicon rubber material.

11. The display device of claim 1, wherein the cover layer further comprises a support configured to support the cover frame from the substrate.

12. The display device of claim 1, further comprising a driver connected to a side of the substrate, and configured to drive the substrate to be radially stretched.

13. The display device of claim 12, wherein the driver comprises an expanding pulley structure.

14. A display device that is convertible between a first structure and a second structure that is radially stretched from the first structure, the display device comprising:
a substrate;
a plurality of light-emitting diodes on the substrate; and
a cover layer comprising:
a cover frame on the substrate and comprising an opaque material; and
a cover opening in the cover frame and overlapping with the plurality of light-emitting diodes,
wherein the plurality of light-emitting diodes comprises:
a plurality of first light-emitting diodes located along a first line, the first line being a virtual closed curve having a first center point as a center; and
a plurality of second light-emitting diodes located along a second line, the second line being a virtual closed curve having the first center point as the center and surrounding around the first line, and
wherein a difference between a distance between the first center point and the first line and a distance between the first line and the second line in the second structure is less than a difference between a distance between the first center point and the first line and a distance between the first line and the second line in the first structure.

15. The display device of claim 14, wherein the cover opening comprises:
a plurality of first cover openings located along a third line, the third line being a virtual closed curve having the first center point as the center; and
a plurality of second cover openings located along a fourth line, the fourth line being a virtual closed curve having the first center point as the center and surrounding around the third line, and
wherein, in each of the first structure and the second structure, a distance between the first center point and the third line is equal to a distance between the third line and the fourth line.

16. The display device of claim 15, wherein, in the second structure, the first line overlaps with the third line.

17. The display device of claim 15, wherein, in the second structure, the second line overlaps with the fourth line.

18. The display device of claim 14, wherein, in the first structure, a distance between the first center point and the first line is greater than a distance between the first line and the second line.

19. The display device of claim 15, wherein, in each of the first structure and the second structure, at least one of the first line, the second line, the third line, or the fourth line is circular.

20. The display device of claim 14, further comprising a driver connected to a side of the substrate, and configured to drive the substrate to be radially stretched or reduced.
